(19) United States
(12) Patent Application Publication
(10) Pub. No.: US 2024/0195147 A1
(43) Pub. Date: Jun. 13, 2024

(54) LASER PULSE EMITTING INTEGRATED CIRCUIT MODULE, A METHOD OF MAKING THEREOF, AND A LASER PULSE EMITTING SYSTEM

(71) Applicants: SHANGHAI XIAOBEN TECHNICAL SERVICE CO., LTD., Shanghai (CN); SHANGHAI METAPWR ELECTRONICS CO., LTD, Shanghai (CN)

(72) Inventor: Jianhong ZENG, Shanghai (CN)

(73) Assignees: SHANGHAI XIAOBEN TECHNICAL SERVICE CO., LTD., Shanghai (CN); SHANGHAI METAPWR ELECTRONICS CO., LTD, Shanghai (CN)

(21) Appl. No.: 18/585,062

(22) Filed: Feb. 23, 2024

Related U.S. Application Data
(63) Continuation of application No. PCT/CN2022/105993, filed on Jul. 15, 2022.

(30) Foreign Application Priority Data
Sep. 1, 2021 (CN) 202111023149.8

(51) Int. Cl. H01S 5/042; H01S 5/022; H01S 5/024

(52) U.S. Cl. CPC H01S 5/0428; H01S 5/022; H01S 5/04256; H01S 5/02469

(57) ABSTRACT

A laser pulse emitting integrated circuit module, a method of making thereof, and a laser pulse emitting system are provided. The laser pulse emitting integrated circuit module comprises a laser emitting device D1, a switch S1 and a decoupling capacitor C1. The D1, the S1 and the C1 are connected in pairs to form an energy storage circuit. The energy storage circuit comprises N energy storage sub-circuits which are distributed at N adjacent sub-space positions of the laser pulse emitting integrated circuit module. The energy storage sub-circuits are arranged in the corresponding sub-space positions to inhibit inductive coupling. The equivalent Loop is far smaller than that of a traditional scheme, the equivalent Loop inductor with the equivalent Loop inductance of 0.5 times or even more than 0.25 times can be easily obtained. The rising edge falling edge speed of the laser pulse can be doubled or even more than four times.

### CROSS-REFERENCE TO RELATED APPLICATION

This application is a continuation of international PCT application serial no. PCT/CN2022/105993, filed on Jul. 15, 2022, which claims the priority benefit of China application no. 202111023149.8, filed on Sep. 1, 2021. The entirety of each of the above mentioned patent applications is hereby incorporated by reference herein and made a part of this specification.

### TECHNICAL FIELD

The present invention relates to the field of power electronic technology, and more particularly to a laser pulse emitting integrated circuit module, chip, a method of making thereof, and a laser pulse emitting system that shorten rising edge time and falling edge time.

### DESCRIPTION OF RELATED ART

FIG. 1A shows a schematic circuit diagram of a laser pulse emitting module in the prior art, wherein laser emitting device D1 is a light-emitting diode, such as a laser diode (all follow-up laser diodes are taken as examples); Vin is direct-current power supply, and in order to reduce the influence of the transmission line, a capacitor Cin is often placed in a near place; switch S1 is a driving switch; switch driving unit Q1 is a switch driving unit for switch S1; Q2 is an operation control unit controlled by switch S1; decoupling capacitor C1 is a decoupling capacitor; R1 is a power supply resistor or an equivalent resistor; and L1 is a power supply equivalent inductor. When Q2 generates a control pulse, which is a control signal for the switch driving unit Q1, and switch S1 is turned on controlled by the switch driving unit Q1, the energy of the power supply Vin can be given to the current flowing laser emitting device D1 through L1 and R1, and laser emitting device D1 receives energy and emits laser. On the contrary, when Q2 turns off, switch S1 is turned off driven by switch driving unit Q1, the energy of the power supply Vin cannot pass through L1 and R1 to laser emitting device D1, and emission laser is stopped. The loop formed by Vin, laser emitting device D1 and switch S1 is often large, and the equivalent inductors L1 and the power supply resistor R1 are also relatively large, so that the rising and falling speeds of the current flowing the laser emitting device D1 are limited. Due to the slow rising and falling speed, the frequency of light emission is hindered, and the application scene and effect are limited.

Therefore, in practical application, the decoupling capacitor C1 is added, so that the energy storage loop L2 are reduced in different solutions, the L2 loop is as small as possible, the inductance of L2 is reduced, and rapid current rising and falling of the energy decoupling capacitor C1 are achieved.

FIG. 1B is a cross-sectional view of a typical existing implementation method: decoupling capacitor C1, laser emitting device D1 and switch S1 are laid on a PCB as close as possible. Obviously, the scheme is simple to manufacture, low cost and very thin in height. However, the occupied region on the PCB is large. The L2 Loop is also large because the current path is too long, even if a multi-layer PCB and a better Layout are used, the inductance of L2 is as high as 600 pH.

FIG. 1C is a cross-sectional view of a prior art, namely, laser emitting device D1 and switch S1 are respectively arranged on an independent PCB, and then the two PCBs are connected through a thin multi-layer flexible PCB. In order to further reduce the region, switch driving unit Q1, Q2 and switch S1 are integrated in an IC through a PCB or encapsulation process. decoupling capacitor C1 is also often placed on the PCB of the IC1. The advantages are obvious, that is, the occupied region is greatly reduced, and due to the introduction of the extremely thin multi-layer flexible PCB, although the distance of the loop is increased, the region of the loop can be greatly reduced, so that the L2 loop is controlled to be similar to that of FIG. 1B.

Therefore, L2 Loop have limitations in FIG. 1B and FIG. 1C. Due to the fact that di/dt=V/L, if the current change speed needs to be increased, the rising edge time or the falling edge time of the light pulse needs to be shortened, and the only way is improving the power supply voltage Vin, so that the loss of light-emitting device is increased.

In a mobile phone application scene, a lithium battery is used for supplying power (about 4V), and L2=600 pH is taken as an example, when a VCSEL (Vertical Cavity Surface Emitting Laser chip and a voltage drop is about 2V) used for driving a 10 ampere-level VCSEL, the durations of the rising edge and the falling edge of the VCSEL are about 3 nS, and if the duration is expected to be reduced to Ins, the current of the VCSEL needs be reduced to about 3 A, and the detection distance needs to be shortened. The absolute error of the duration InS is equivalent to about 30 cm for ToF (Time of Flight) ranging.

Therefore, this application provides the Laser pulse emitting module capable of shortening the durations of the rising edge and falling edge time of the light emitting device, the chip and the manufacturing method and system thereof, so that the durations of the rising edge and the falling edge of the light modulation can be shorter than InS.

### SUMMARY

In general, one aspect features a laser pulse emitting integrated circuit module is used for realizing a circuit function for emitting a laser pulse, and comprises the following elements.

At least one laser emitting device D1, which is used for emitting laser pulses.

At least one driving switch S1. The driving switch S1 comprises at least one control electrode and is used for controlling the laser emitting device D1 to be turned on or off.

At least one decoupling capacitor C1, which is used for receiving and storing electric energy provided by the system.

The laser emitting device D1, the driving switch S1 and the decoupling capacitor C1 are connected in pairs to form an energy storage circuit.

When the circuit function for emitting the laser pulse is realizing, the energy storage circuit comprises N energy storage sub-circuits which are distributed at N adjacent sub-space positions of the laser pulse emitting integrated circuit module, and N is an integer greater than or equal to 2.

The energy storage sub-circuits are arranged in the corresponding sub-space positions to inhibit inductive coupling.

Each of the energy storage sub-circuits is controlled by the same control timing. As shown in D1-1 and D1-2, S1-1 and S1-2, and S1-1 and S1-2 are controlled by substantially the same control timing, so that each sub-loop transmits or turns off the laser pulse almost simultaneously, so that each sub-loop is equivalent in parallel, and the equivalent loop inductance is greatly reduced while the total transmission power is ensured.

Implementations of the laser pulse emitting integrated circuit module may include one or more of following features. Two adjacent energy storage sub-circuits share the same laser emitting device D1 and/or the same driving switch S1 and/or the same decoupling capacitor C1.

Implementations of the laser pulse emitting integrated circuit module may include one or more of following features. The laser emitting device D1 comprises a light-emitting chip, the light-emitting chip is a flat semiconductor chip, and the light-emitting chip is provided with a first power electrode with a first electrical property and a second power electrode with a second electrical property.

The light-emitting chip forms a first encapsulation, and the first encapsulation is provided with a top surface and a bottom surface of the first encapsulation, the top surface and the bottom surface are opposite.

The driving switch S1 comprises a switch chip, wherein the switch chip is a flat semiconductor chip, and the switch chip is provided with a first power electrode with a first electrical property and a second power electrode with a second electrical property.

The switch chip forms a second encapsulation, and the second encapsulation is provided with a top surface and a bottom surface of the second encapsulation, the top surface and the bottom surface are opposite.

The first encapsulation and the second encapsulation are parallelly stacked up and down to form a stacked body.

The contact surface between the first encapsulation and the second encapsulation is provided with a first direction and a second direction which are perpendicular to each other.

The energy storage sub-circuits are symmetrically arranged in the stacked body in the second direction.

It should be noted that the first encapsulation and the second encapsulation described in the application may be bare chips passing through a redistribution line, or may be a plastic-packaged chip, and are hereby described.

Implementations of the laser pulse emitting integrated circuit module may include one or more of following features. A deviation of a parallel angle between the overlapped light-emitting chip and the switch chip is in the range of −45° to +45°, and wherein a deviation of between central axes of the light-emitting chip and the switch chip ratio is in the range of 2:3 to 3:2.

Implementations of the laser pulse emitting integrated circuit module may include one or more of following features. The first power electrode of the switch chip is distributed on the top surface of the second encapsulation, and the second power electrode of the switch chip is distributed on the bottom surface of the second encapsulation.

The first power electrode of the light-emitting chip is distributed on the top surface of the first encapsulation, and the second power electrode of the light-emitting chip is distributed on the bottom surface of the first encapsulation.

The first power electrode of the switch chip is electrically connected with the second power electrode of the light-emitting chip.

The decoupling capacitor C1 in each energy storage sub-circuits is arranged outside the stacked body, and the two ends of the decoupling capacitor C1 in each energy storage sub-circuit are electrically connected with the second power electrode of the switch chip and the first power electrode of the light-emitting chip respectively.

Implementations of the laser pulse emitting integrated circuit module may include one or more of following features. The first power electrode and second power electrode of the switch chip are respectively arranged on the top surface of the second encapsulation.

The first power electrode of the light-emitting chip is distributed on the top surface of the first encapsulation, and the second power electrode of the light-emitting chip is distributed on the bottom surface of the first encapsulation.

The first power electrode of the switch chip is electrically connected with the second power electrode of the light-emitting chip.

The decoupling capacitor C1 in each energy storage sub-circuit is arranged outside of the stacked body, and the two ends of the decoupling capacitor C1 in each energy storage sub-circuit are electrically connected with the second power electrode of the switch chip and the first power electrode of the light-emitting chip respectively.

Implementations of the laser pulse emitting integrated circuit module may include one or more of following features. The decoupling capacitor C1 in each energy storage sub-circuits is integrated in the second encapsulation.

In the second encapsulation, a second electrode of the decoupling capacitor C1 in each energy storage sub-circuit is electrically connected with a second power electrode of the switch chip.

The first power electrode of the switch chip and a first power electrode of the decoupling capacitor are respectively arranged on the top surface of the second encapsulation.

The first power electrode of the light-emitting chip is distributed on the top surface of the first encapsulation, and the second power electrode of the light-emitting chip is distributed on the bottom surface of the first encapsulation.

The first power electrode of the switch chip is electrically connected with the second power electrode of the light-emitting chip.

The first electrode of the decoupling capacitor is electrically connected with the first power electrode of the light-emitting chip from the outside of the stacked body.

Implementations of the laser pulse emitting integrated circuit module may include one or more of following features. The decoupling capacitor C1 is integrated in the second encapsulation.

In the second encapsulation, a second electrode of the decoupling capacitor C1 is electrically connected with a second power electrode of the switch chip.

First power electrode of switch chip and a first electrode of decoupling capacitor are respectively arranged on the top surface of the second encapsulation.

The first power electrode of the light-emitting chip is distributed on the top surface of the first encapsulation, and the second power electrode of the light-emitting chip is distributed on the bottom surface of the first encapsulation.

The first power electrode of the switch chip is electrically connected with the first power electrode of the light-emitting chip.

The first electrode of the decoupling capacitor is electrically connected with the second power electrode of the light-emitting chip from the outside of the stacked body.

Implementations of the laser pulse emitting integrated circuit module may include one or more of following features. At least some of the energy storage sub-circuits share the same decoupling capacitor C1.

Implementations of the laser pulse emitting integrated circuit module may include one or more of following features. The decoupling capacitor C1 is integrated in the second encapsulation.

In the second encapsulation, a second electrode of the decoupling capacitor C1 is electrically connected with second power electrode of the switch chip.

The first power electrode of switch chip and first power electrodes of decoupling capacitor are respectively arranged on the top surface of the second encapsulation.

The first power electrode of a light-emitting chip and second power electrode of a light-emitting chip are respectively arranged on the bottom surface of the first encapsulation.

The first power electrode of the switch chip is electrically connected with the first power electrode of the light-emitting chip, and the first electrode of the decoupling capacitor is electrically connected with the second power electrode of the light-emitting chip.

Implementations of the laser pulse emitting integrated circuit module may include one or more of following features. The laser pulse emitting integrated circuit module further comprises a plurality of switch driving units Q1. The switch driving units Q1 are used for turning on and off of the switch chips, and each switch driving unit Q1 drives at least one switch chip.

The switch driving unit Q1 is integrated in the second encapsulation.

In the second encapsulation, the switch driving unit Q1 is electrically connected with a control electrode of the switch chip.

Implementations of the laser pulse emitting integrated circuit module may include one or more of following features. The laser pulse emitting integrated circuit module further comprises an operation control unit Q2. The operation control unit Q2 is used for outputting a switch signal to the switch driving unit Q1, and the operation control unit Q2 drives the switch chip through at least one switch driving unit Q1.

The operation control unit Q2 is integrated in the second encapsulation.

In the second encapsulation, the operation control unit Q2 is electrically connected with the switch driving unit Q1.

Implementations of the laser pulse emitting integrated circuit module may include one or more of following features. The laser pulse emitting integrated circuit module further comprises a plurality of power supply capacitors C2, and the power supply capacitor C2 is used for providing energy for the switch driving unit Q1.

The power supply capacitor C2 is integrated in the second encapsulation.

In the second encapsulation, two ends of each power supply capacitor C2 are electrically connected with a power supply electrode and a grounding electrode of the switch driving unit Q1 respectively.

Implementations of the laser pulse emitting integrated circuit module may include one or more of following features. The decoupling capacitor C1 is integrated in the first encapsulation.

In the first encapsulation, a second electrode of the decoupling capacitor C1 is electrically connected with second power electrode of the light-emitting chip.

The first power electrode of the switch chip and the second power electrode of the switch chip are respectively arranged on the top surface of the second encapsulation.

The first power electrode of the light-emitting chip and a first electrode of the decoupling capacitor are respectively arranged on the bottom surface of the first encapsulation.

The first power electrode of the switch chip is electrically connected with the first power electrode of the light-emitting chip, and the second power electrode of the switch chip is electrically connected with a first electrode of the decoupling capacitor.

Implementations of the laser pulse emitting integrated circuit module may include one or more of following features. The first power electrode of the light-emitting chip or the second power electrode of the light-emitting chip is formed on the bottom surface of the first encapsulation through a TSV technology.

Implementations of the laser pulse emitting integrated circuit module may include one or more of following features. The first encapsulation and the second encapsulation are formed the stacked body by inverted manner.

Implementations of the laser pulse emitting integrated circuit module may include one or more of following features. The first power electrode and the second power electrode of the light-emitting chip of the first encapsulation extend in a first direction and are distributed alternately in a second direction.

The first power electrode of switch chip and a first electrode of decoupling capacitor of the second encapsulation extend in a first direction and are distributed alternately in a second direction.

Implementations of the laser pulse emitting integrated circuit module may include one or more of following features. The first power electrode and the second power electrode of the light-emitting chip of the first encapsulation are distributed alternately in the first direction and the second direction respectively.

The first power electrode of the switch chip and a first electrode of the decoupling capacitor of the second encapsulation are distributed alternately in the first direction and the second direction respectively.

Implementations of the laser pulse emitting integrated circuit module may include one or more of following features. First power electrode of the light-emitting chip and a first electrode of decoupling capacitor of the first encapsulation are extended in a first direction and are distributed alternately in a second direction.

The first power electrode and second power electrode of the switch chip of the second encapsulation extend in a first direction and are distributed alternately in the second direction.

Implementations of the laser pulse emitting integrated circuit module may include one or more of following features. The first power electrode of the light-emitting chip and the first electrode of the decoupling capacitor of the first encapsulation are distributed alternately in the first direction and the second direction respectively.

The first power electrode and the second power electrode of the switch chip of the second encapsulation are distributed alternately in the first direction and the second direction respectively.

Implementations of the laser pulse emitting integrated circuit module may include one or more of following features. The light-emitting chip is a vertical cavity surface emitting laser chip, and a heat dissipation device is arranged at the bottom of the stacked body.

Implementations of the laser pulse emitting integrated circuit module may include one or more of following features. The light-emitting chip is an edge emitting chip, and the top and the bottom of the stacked body are respectively provided with a heat dissipation device.

Implementations of the laser pulse emitting integrated circuit module may include one or more of following features. The laser pulse emitting integrated circuit module further comprises the following elements.

A D1 functional region which is integrated with a D1 semiconductor structure for realizing the function of a laser emitting device D1. The first surface of the D1 functional region is provided with first power electrodes of D1 functional region with a first electrical property and second power electrodes of D1 functional region with a second electrical property.

A S1 functional region which is integrated with a C1 semiconductor structure for realizing the function of a decoupling capacitor C1 and is integrated with an S1 semiconductor structure for realizing the function of a driving switch S1. The C1 semiconductor structure is electrically connected with an S1 semiconductor structure, and the S1 functional region is provided with first power electrodes of the S1 functional region with a first electrical property and second power electrodes of the S1 functional region with a second electrical property.

A dielectric bonding layer which is disposed between the D1 functional region and the S1 functional region. The dielectric bonding layer is bonded to the D1 functional region and the S1 functional region. A plurality of first conductors and a plurality of second conductors are provided in the dielectric bonding layer. The first conductor electrically connects the first power electrodes of the D1 functional region to the second power electrodes of the S1 functional region, and the second conductor electrically connects the second power electrodes of the D1 functional region to the first power electrodes of the S1 functional region.

Implementations of the laser pulse emitting integrated circuit module may include one or more of following features. The laser pulse emitting integrated circuit module further comprises the following elements.

A D1 functional region which is integrated with a C1 semiconductor structure for realizing the function of a decoupling capacitor C1, and is integrated with a D1 semiconductor structure for realizing the function of a laser emitting device D1. The C1 semiconductor structure is electrically connected with the D1 semiconductor structure, and the first surface of the D1 functional region is provided with first power electrodes of the D1 functional region with the first electrical property and second power electrodes of the D1 functional region with the second electrical property.

A S1 functional region which is integrated with an S1 semiconductor structure for realizing the functional of a driving switch S1. First power electrodes of S1 functional region with a first electrical property and second power electrodes of S1 functional region with a second electrical property are provided on the S1 functional region.

A dielectric bonding layer which is disposed between the D1 functional region and the S1 functional region. The dielectric bonding layer is bonded to the D1 functional region and the S1 functional region. A plurality of first conductors and a plurality of second conductors are provided in the dielectric bonding layer. The first conductor electrically connects the first power electrodes of the D1 functional region to the second power electrodes of the S1 functional region, and the second conductor electrically connects the second power electrodes of the D1 functional region to the first power electrodes of the S1 functional region.

Implementations of the laser pulse emitting integrated circuit module may include one or more of following features. The surface of the dielectric bonding layer is provided with a third direction and a fourth direction which are perpendicular to each other.

The first conductor and the second conductor respectively are extended in a first direction and in a third direction, and the first conductor and the second conductor are distributed alternately in a fourth direction.

Implementations of the laser pulse emitting integrated circuit module may include one or more of following features. The surface of the dielectric bonding layer is provided with a third direction and a fourth direction which are perpendicular to each other.

The first conductor and the second conductor are distributed alternately in a third direction and a fourth direction.

Implementations of the laser pulse emitting integrated circuit module may include one or more of following features. The laser pulse emitting integrated circuit module further comprises the following elements

A flexible connector which is arranged on the bottom surface of the second encapsulation. The flexible connector is used for flexibly connecting the second encapsulation with the client mainboard and electrically connecting the second encapsulation with the client mainboard.

Implementations of the laser pulse emitting integrated circuit module may include one or more of following features. The laser pulse emitting integrated circuit module further comprises the following elements.

A heat dissipation shell, which is arranged on the outer side of the laser module. An opening is formed in at least one direction of the heat dissipation shell, so that the heat dissipation shell does not block laser pulses to be emitted, and the flexible connector is not blocked to extend to the client mainboard.

In general, one aspect features a method of making the aforementioned laser pulse emitting integrated circuit module comprises the following steps.

Manufacturing a D1 functional region on a wafer, wherein the D1 functional region is integrated with a D1 semiconductor structure for realizing the function of a laser emitting device D1, and first power electrodes of the D1 functional region and second power electrodes of the D1 functional region are formed on the first surface of the D1 functional region.

Growing a dielectric bonding layer over a first surface of the D1 functional region.

Disposing an SOI stack on the dielectric bonding layer and forming an S1 functional region on the SOI stack; wherein the S1 functional region is integrated with a C1 semiconductor structure for realizing the function of a decoupling capacitor C1 and is integrated with an S1 semiconductor structure for realizing the function of a driving switch S1, the C1 semiconductor structure is electrically connected with the S1 semiconductor structure, and the S1 functional region is provided with first power electrodes of the S1 functional region and second power electrodes of the S1 functional region.

Forming a plurality of trenches in the dielectric bonding layer and the S1 functional region, wherein the positions of the trenches are in one-to-one correspondence with the first power electrodes of the D1 functional region and the second power electrodes of the D1 functional region, so that the first power electrodes of the D1 functional region and the second power electrodes of the D1 functional region are exposed at the bottom of the trench.

Forming a plurality of first conductors and a plurality of second conductors in the trench, wherein the first conductor electrically connects the first power electrodes of the D1 functional region to the second power electrodes of the S1 functional region, and the second conductor electrically connects the second power electrodes of the D1 functional region to the first power electrodes of the S1 functional region.

In general, one aspect features a method of making the aforementioned laser pulse emitting integrated circuit module comprises the following steps.

Manufacturing a D1 functional region on a wafer, wherein the D1 functional region is integrated with a C1 semiconductor structure for realizing the function of a decoupling capacitor C1 and is integrated with a D1 semiconductor structure for realizing the function of a laser emitting device D1, the C1 semiconductor structure is electrically connected with the D1 semiconductor structure, and the first surface of the D1 functional region is provided with first power electrodes with a first electrical property and second power electrodes with a second electrical property.

Growing a dielectric bonding layer over a first surface of the D1 functional region.

Arranging an SOI stack on the dielectric bonding layer, and forming an S1 functional region on the SOI stack; wherein the S1 functional region is integrated with an S1 semiconductor structure for realizing the function of a driving switch S1, and the S1 functional region is provided with first power electrodes of S1 functional region with a first electrical property and second power electrodes of S1 functional region with a second electrical property;

Forming a plurality of trenches in the dielectric bonding layer and the S1 functional region, wherein the positions of the trenches are in one-to-one correspondence with the first power electrodes of the D1 functional region and the second power electrodes of the D1 functional region, so that the first power electrodes of the D1 functional region and the second power electrodes of the D1 functional region are exposed at the bottom of the trench.

Forming a plurality of first conductors and a plurality of second conductors in the trench, wherein the first conductor electrically connects the first power electrodes of the D1 functional region to the second power electrodes of the S1 functional region, and the second conductor electrically connects the second power electrodes of the D1 functional region to the first power electrodes of the S1 functional region.

In general, one aspect features an encapsulation according to the first encapsulation in the aforementioned laser pulse emitting integrated circuit module. The light-emitting chip is a vertical cavity surface emitting laser (VCSEL) chip, the first power electrode of the light-emitting chip on the same surface of the light-emitting window is electrically connected to the surface disposed the second power electrode of the light-emitting chip through a through silicon via (TSV) technology.

Or, the light-emitting chip is an edge emitting laser (EEL) chip. The EEL chip comprises a plurality of light-emitting chip sub-units, and the electrical properties of the adjacent light-emitting chip sub-units are opposite.

Another aspect features an encapsulation according to the second encapsulation in the aforementioned laser pulse emitting integrated circuit module.

In general, one aspect features a laser pulse emitting integrated circuit system, comprises the following elements.

The aforementioned laser pulse emitting integrated circuit module and a plurality of device groups of power supply loop.

The device group of power supply loop comprises a power supply capacitor Cin and a damping resistor R1 which are connected in series.

Each device group of power supply loop and at least one energy storage sub-circuit form a sub-power supply loop.

The electric connection position of the power supply capacitor Cin and the damping resistor R1 is electrically connected with the power supply electrode of the laser pulse emitting system, the other end of the power supply capacitor Cin is grounded, and the other end of the damping resistor R1 is electrically connected with the power supply electrode of the energy storage sub-circuit.

The details of one or more embodiments of the application are set forth in the accompanying drawings and description below. Other features, objects, and advantages of the application will be apparent from the description and drawings, and from the claims.

### BRIEF DESCRIPTION OF THE DRAWINGS

In order to more clearly describe the technical solutions in the embodiments of the invention or the prior art, the drawings to be used in the description of the embodiments or the prior art will be briefly introduced below. It will be apparent to those skilled in the art that the drawings in the following description are only some of the invention, and that other drawings may be obtained from the drawings without any creative works.

FIG. 1A is a schematic circuit diagram of a light emitting device of prior art;

FIG. 1B is a cross-sectional view of a light emitting device of prior art.

FIG. 1C is another cross-sectional view of the light emitting device in the prior art.

FIG. 2 is a schematic circuit diagram of a Laser pulse emitting module of embodiment.

FIG. 3 is a schematic diagram of an laser pulse emitting module of a Laser pulse emitting module of embodiment.

FIG. 4A to FIG. 4C are cross-sectional views of FIG. 3.

FIG. 5A to FIG. 5C are schematic circuit structure diagrams of a partial device shared by energy storage sub-circuits of embodiment;

FIG. 6A to FIG. 6C are schematic structural diagrams of different types of light-emitting chips of embodiment;

FIG. 6D and FIG. 6E are schematic structural diagrams of different types of switch chips of embodiment;

FIG. 7A and FIG. 7B are schematic diagrams of a switch chip with the two power electrodes located on the upper surface and the lower surface matched with a light-emitting chip with two power electrodes located on the upper surface and the lower surface;

FIG. 8A to FIG. 8E are schematic diagrams of a switch chip with the two power electrodes located on the same surface matched with a light-emitting chip with the two power electrodes located on the upper surface and the lower surface;

FIG. 9 is a schematic diagram of a switch chip with the two power electrodes located on the same surface and a light-emitting chip with the two power electrodes located on the same surface;

FIG. 10A and FIG. 10B are matching schematic diagrams after the first encapsulation and the second encapsulation are divided into a plurality of sub-units;

FIG. 11A is a cross-sectional view of a VCSEL chip including a plurality of sub-units;

FIG. 11B is a cross-sectional view of an EEL chip;

FIG. 11C is a layout diagram of electrodes of a light-emitting chip in some embodiments;

FIG. 11D is a layout diagram of electrodes of a light-emitting chip in some embodiments;

FIG. 11E is a cross-sectional view of a second encapsulation integrated with decoupling capacitor C1;

FIG. 11F is an electrodes layout diagram of a second encapsulation integrated with decoupling capacitor C1 in conjunction with FIG. 11C;

FIG. 11G is an electrodes layout diagram of a second encapsulation integrated with decoupling capacitor C1 in conjunction with FIG. 11D;

FIG. 12A is a cross-sectional view of a switch chip including a plurality of sub-units;

FIG. 12B is an electrodes layout diagram of a switch chip in some embodiments;

FIG. 12C is an electrodes layout diagram of a switch chip in some other embodiments;

FIG. 12D is a cross-sectional view of a first encapsulation integrated with decoupling capacitor C1 and VCSEL chips;

FIG. 12E is a cross-sectional view of a first encapsulation integrated with decoupling capacitor C1 and EEL chips;

FIG. 12F is an electrodes layout diagram of a first encapsulation integrated with decoupling capacitor C1 in conjunction with FIG. 12B;

FIG. 12G is an electrodes layout diagram of a first encapsulation integrated with decoupling capacitor C1 in conjunction with FIG. 12C;

FIG. 13A is a schematic diagram of a second encapsulation integrated with switch driving unit Q1;

FIG. 13B is a schematic diagram of a second encapsulation integrated with switch driving unit Q1 and decoupling capacitor C2;

FIG. 13C is a schematic diagram of a second encapsulation integrated with switch driving unit Q1 and Q2;

FIG. 14A is a schematic diagram of a second encapsulation integrated with switch driving unit Q1, Q2, decoupling capacitor C1 and a switch chip;

FIG. 14B is a schematic diagram of a stack formed by flip-chip interconnection of a light emitting chip and a second encapsulation of FIG. 14A;

FIG. 14C is a schematic diagram of a magnetic pulse emitting chip manufactured by using a chip-level integration technology;

FIG. 15 is a schematic circuit diagram of a laser pulse emission system of embodiment;

FIG. 16A to FIG. 16E are flowcharts of a method for manufacturing a laser pulse emitting chip of embodiment;

FIG. 16F is a schematic diagram of a laser pulse emitting chip of embodiment;

FIG. 16G is a schematic diagram of a laser pulse emitting chip of another embodiment;

FIG. 17 is a parameter comparison diagram of embodiment and the prior art.

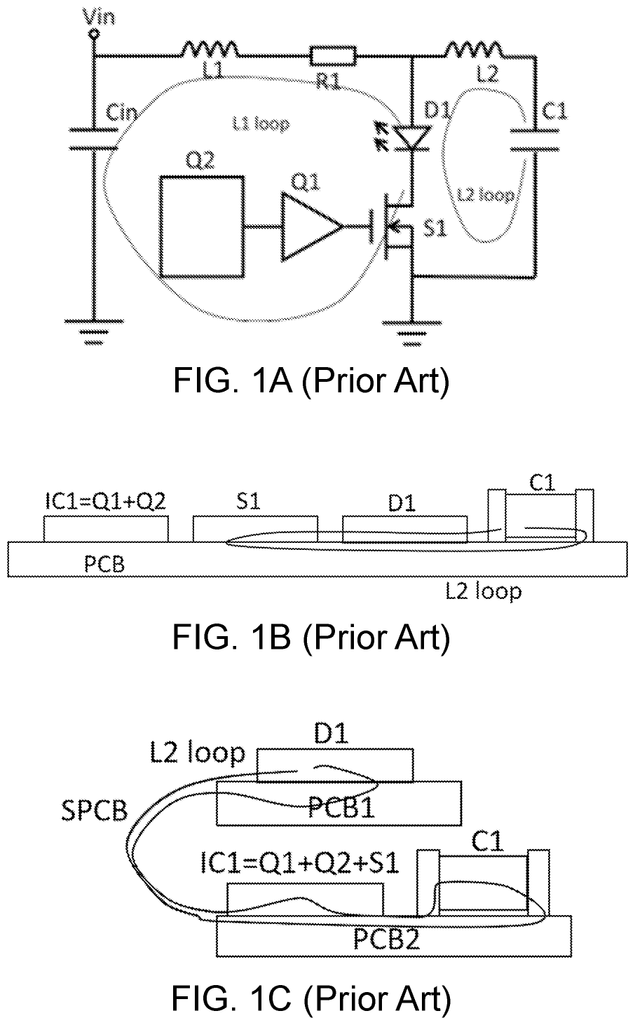

### DESCRIPTION OF THE EMBODIMENTS

The present application discloses various embodiments or examples of implementing the thematic technological schemes mentioned. To simplify the disclosure, specific instances of each element and arrangement are described below. However, these are merely examples and do not limit the scope of protection of this application. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

FIG. 2 shows a schematic circuit diagram of a laser pulse emitting module. In some embodiments, the inductance of L2 is minimized, that is, the loop inductance of laser emitting device D1, the driving switch S1 and the decoupling capacitor C1 is reduced as a target.

Due to the requirement of the emitting power, the laser emitting device D1, the driving switch S1 and the decoupling capacitor C1 need to be supported by a certain size, even if the three elements are placed tightly, the limit Loop inductor caused by the size of the three elements is also arranged, and the 600 pH is basically a result after close placement.

In some embodiments, as shown in FIG. 2, three key elements according to the aforementioned are divided into at least two sub-loops and connected in parallel. In this way, the size of each element of each sub-loop is smaller than that of the original loop, the loop inductance is small, and at least two inductors are connected in parallel, so that the loop inductance is further reduced. If two equal sub-loops are connected in parallel, the equivalent inductance has an opportunity to be one quarter of the original; if three equal sub-loops are connected in parallel, the equivalent inductance will be one-ninth of the original; and so on.

Therefore, the laser pulse emitting module which is used for realizing the circuit functions of laser pulse emission, and the laser pulse emitting module comprises:
at least one laser emitting device D1 is used for emitting laser pulses;
at least one driving switch S1, wherein the driving switch S1 comprises at least one control electrode for controlling the on and off of the laser emitting device D1; and
at least one decoupling capacitor C1 is used for receiving and storing electric energy provided by the system;
the laser emitting device D1, the driving switch S1 and the decoupling capacitor C1 are respectively provided with at least two power electrodes;
the laser emitting device D1, the driving switch S1 and the decoupling capacitor C1 are connected in pairs to form an energy storage circuit;
When the driving switch S1 is conducted, electric energy stored in decoupling capacitor C1 flows through laser emitting device D1, and a laser pulse is emitted by laser emitting device D1 to form a laser pulse rising edge and to maintain the laser pulse intensity;

When the driving switch S1 is turned off or the electric energy stored in decoupling capacitor C1 is insufficient, laser emitting device D1 stops emitting laser pulses to form a laser pulse falling edge and to maintain the electromagnetic waves being low or zero;

During the turn-off period of the driving switch S1, decoupling capacitor C1 continues to receive and store the electric energy provided by the system. In this way, repeated intermittent emission of laser pulses is formed;

When a circuit function of laser pulse emission is realized, the energy storage circuit comprises N energy storage sub-circuits which are distributed at N adjacent sub-space positions of the laser pulse emitting module, and N is an integer greater than or equal to 2;

The energy storage sub-circuits are arranged in the corresponding N sub-space positions to suppress inductive coupling, such as, D1-1, D1-2 to D1-N, S1-1, S1 2 to S1-N, C1-1 and C1-2 to C1-N, switcher in every sub-circuits are controlled by basically the same control time sequence, so that each sub-Loop almost emits or turns off the laser pulses at the same time, so that the sub-Loops are equivalently connected in parallel, and the equivalent Loop inductance is greatly reduced while the total emitting power is guaranteed.

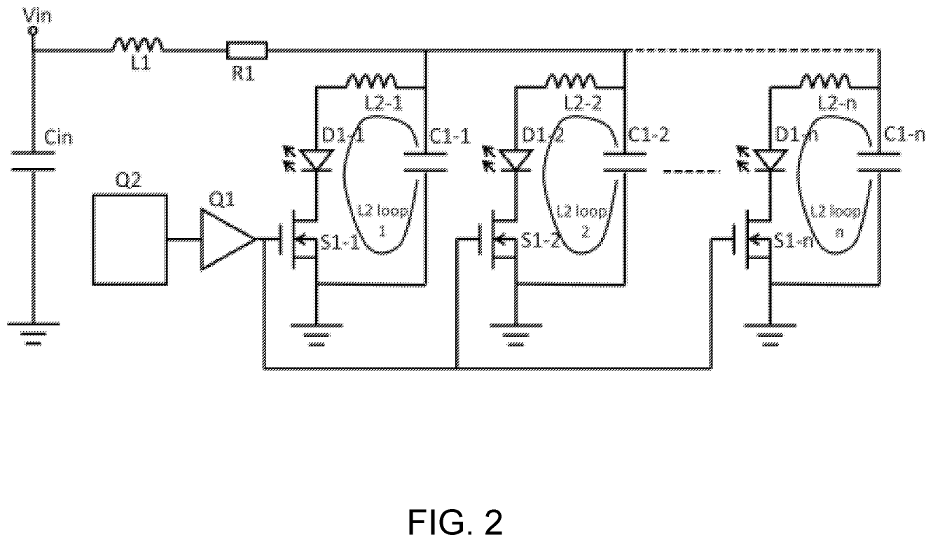

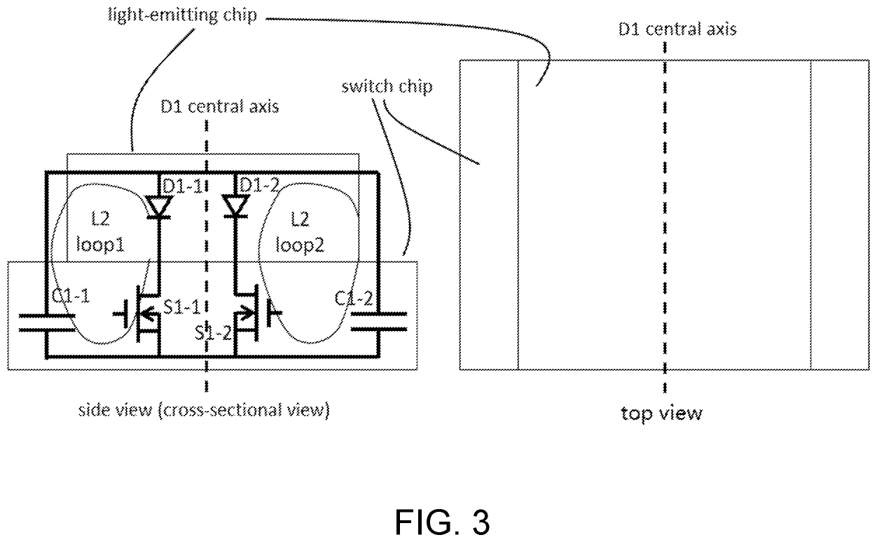

FIG. 3 is a schematic diagram of a specific laser pulse emitting module implementing the circuit structure, the laser emitting device D1 comprising a light-emitting chip, the light-emitting chip being a flat semiconductor chip, and the light-emitting chip having a first power electrode of the light-emitting chip with a first electrical property and a second power electrode of the light-emitting chip with a second electrical property;
the light-emitting chip forms a first encapsulation, and the first encapsulation comprises a upper surface and a lower surface of the first encapsulation, and the upper surface and the lower surface are opposite;
the driving switch S1 comprises a switch chip, the switch chip is a flat semiconductor chip, and the switch chip is provided with a first power electrode of the switch chip with a first electrical property and a second power electrode of the switch chip with a second electrical property;
the switch chip forms a second encapsulation, and the second encapsulation comprising a upper surface and a lower surface, and the upper surface and the lower surface are opposite;
the first encapsulation and the second encapsulation are horizontal stacked up and down to form a stacked body;
the left part and the right part of the stacked body divided by a central axis of the first encapsulation are respectively provided with at least one complete sub-loop comprising laser emitting device D1, the driving switch S1 and decoupling capacitor C1. If the stacked body is axisymmetric, then the two sub-loops are nearly equal.

In FIG. 3, since S1-1 and S1-2 are almost simultaneously turned on, D1-1 is mainly powered by C1-1, and D1-2 are mainly powered by C1-2. Therefore, the current of each sub-Loop is smaller than the total current, and the reduction of the equivalent Loop inductance is realized. It is emphasized that, each sub-unit can be different working regions of the same element, for example, laser emitting device D1 and different positions of the switch chip, and can also be different elements, for example, decoupling capacitor C1 is formed by placing a plurality of capacitor entities in different regions. The core concept thereof is to achieve the effect of FIG. 2 without being exhaustive in the actual physical implementation.

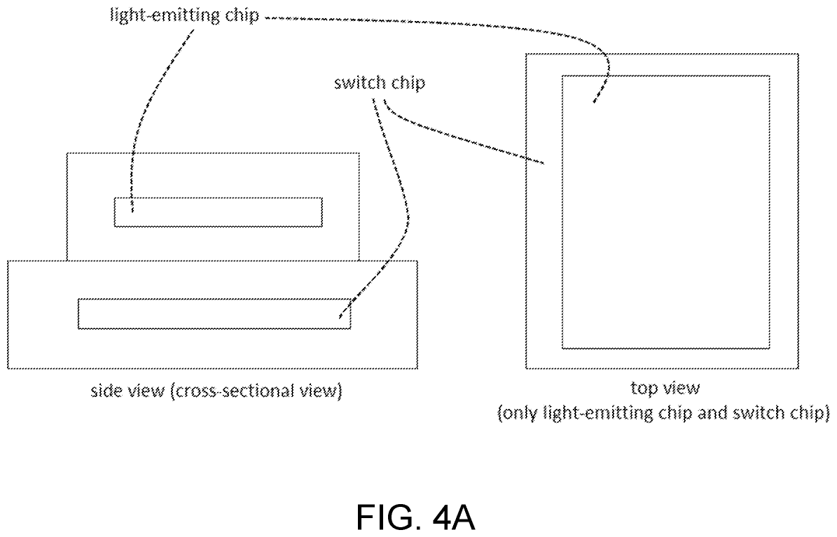

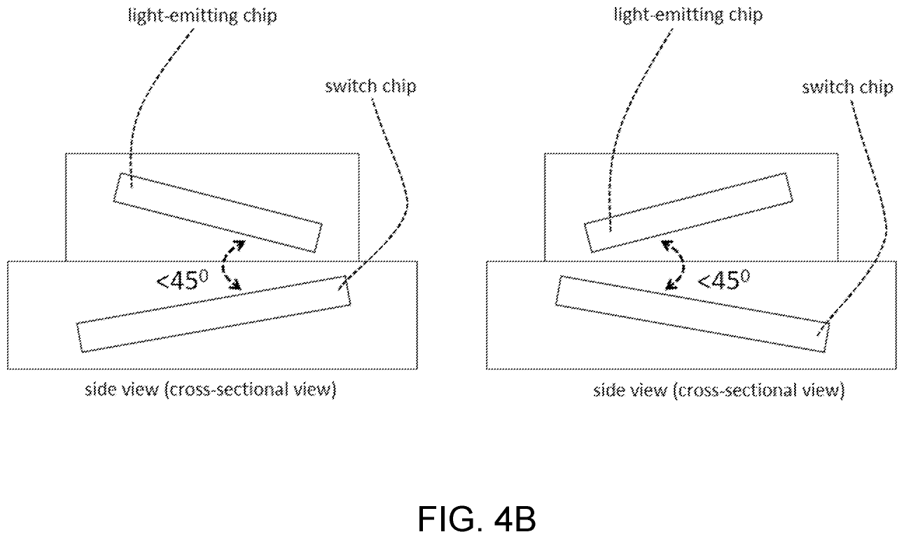

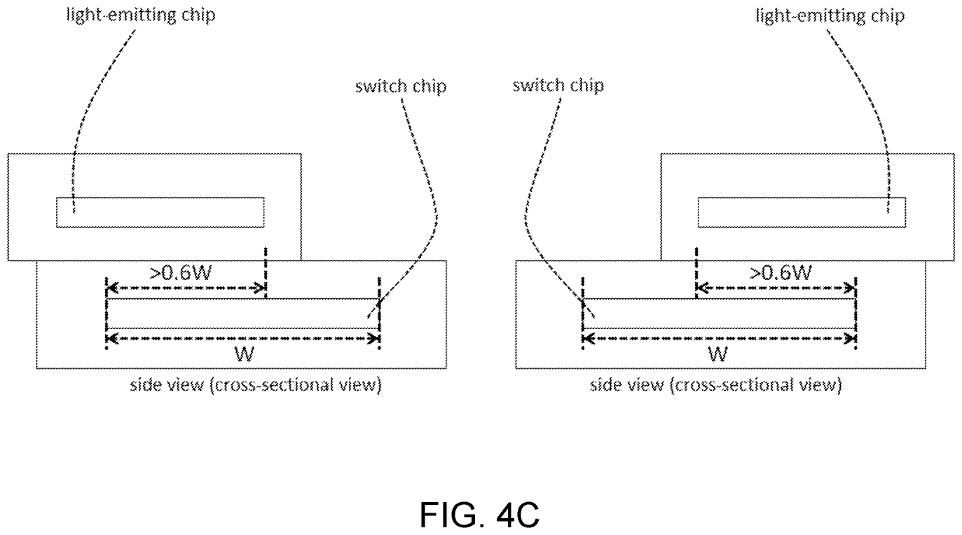

FIGS. 4A-4C are cross-sectional views of FIG. 3. Because of the process precision limitations and the need for other aspects of the system, it's difficult to realize the perfect parallel stacking and axial symmetry. The perfect parallel stacking is the angle of the two chips is 0 degrees. But in the reality, the positive and negative deviations of which the absolute value is less than 45 degrees can be considered to be parallel. The perfect axial symmetry is the ratio of the right part and left part is 1:1, but in the reality, the ratio of the right part and the left part between 2:3 and 3:2 can be considered to be axial symmetry.

The two adjacent energy storage sub-circuits share the same laser emitting device D1 and/or the same driving switch S1 and/or the same decoupling capacitor C1, and if the same sub-unit can be shared between adjacent loops, the effect or spirit of the application is not influenced.

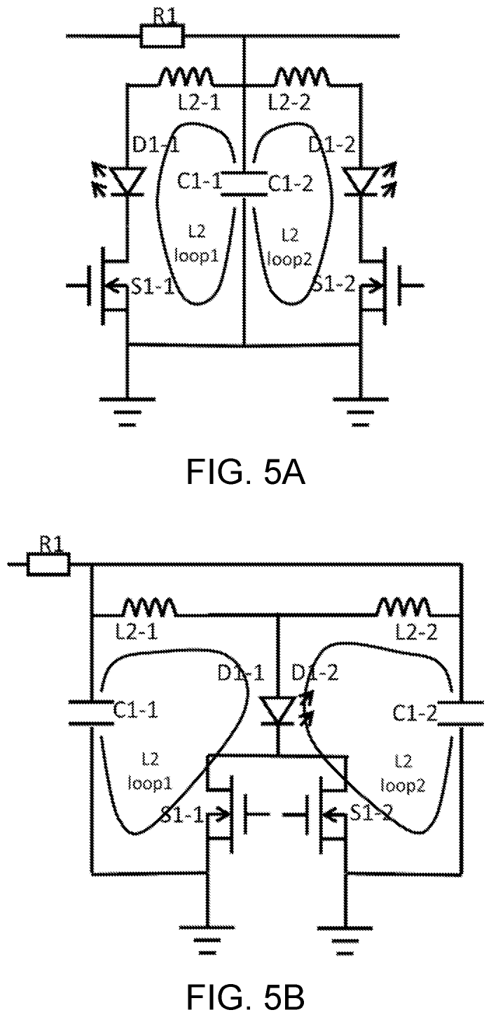

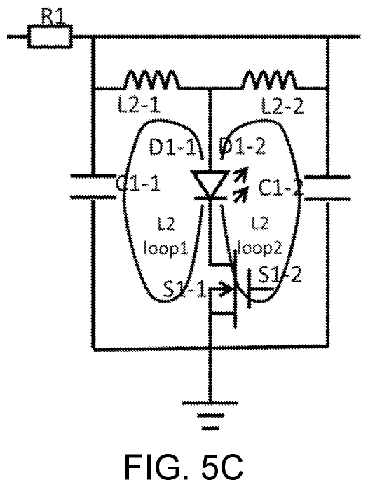

In some embodiments, as shown in FIG. 5A, the two adjacent loops share a same sub-unit of decoupling capacitor C1; as shown in FIG. 5B, the two adjacent loops share a same sub-unit of laser emitting device D1; as shown in FIG. 5C, the two adjacent loops share a same sub-unit of laser emitting device D1, and the two adjacent loops also share a same sub-unit of driving switch S1.

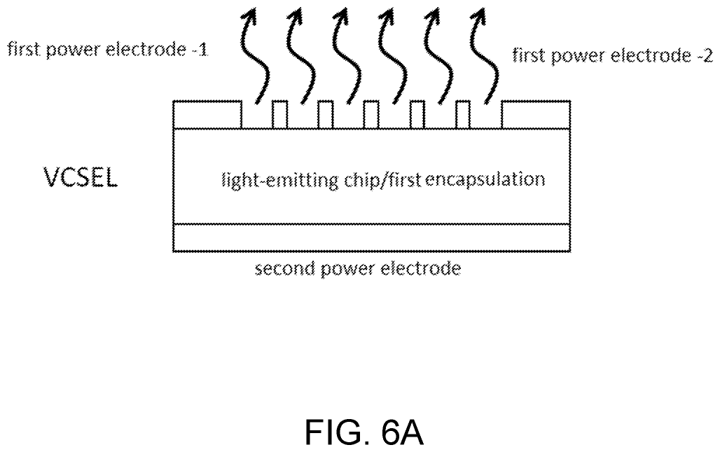

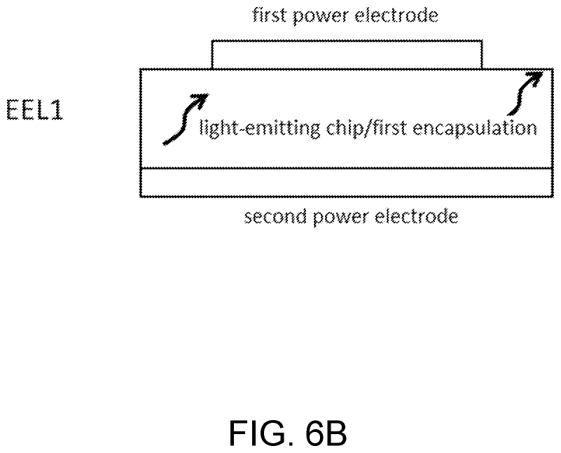

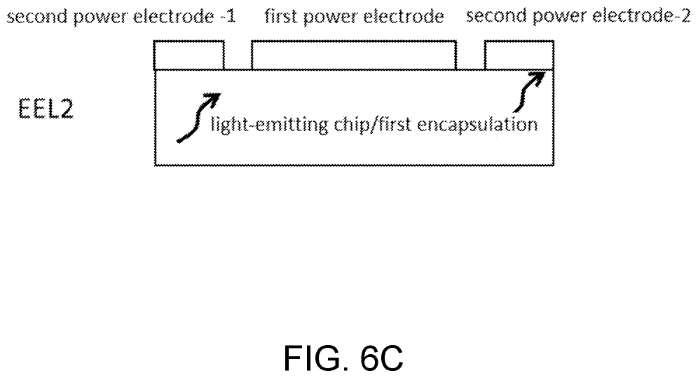

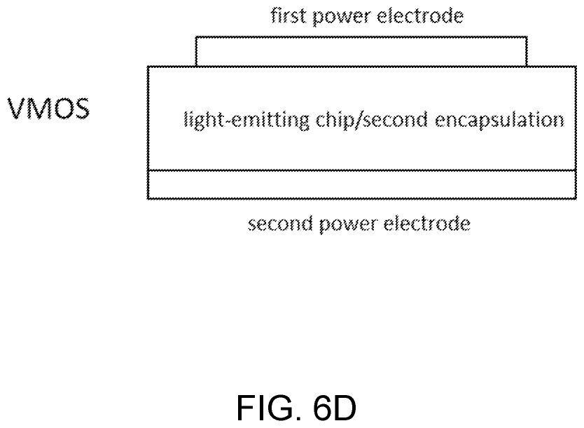

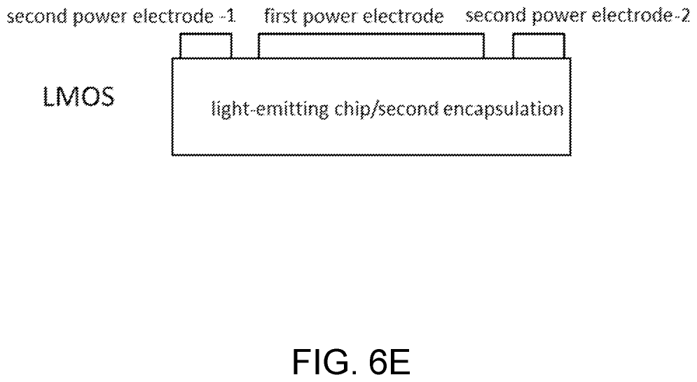

Taking a laser emitting diode as an example, the light-emitting chip is mainly provided with two categories of Vertical Cavity Surface Emitting Laser (VCSEL) chip and Edge-Emitting-Laser (EEL) chip. Embodiments of the two types of light-emitting chips are described below, and as shown in FIGS. 6A to 6C, three types of electrodes are led out for the two types of light-emitting chips.

FIG. 6A shows an electrode lead-out mode of the VCSEL chip. The upper surface metal layer of the VCSEL chip is a first power electrode of the light-emitting chip, the first power electrode can be P (anode) or N (cathode), and the metal layer is provided with a plurality of openings to form a laser emission window, namely a light-emitting array. Obviously, the array is too dense and is not suitable for electrodes to be led out, and in order to reduce the resistance, the electrode 1 is divided into two parts, namely the left side and the right side, which are led out in parallel; and the metal layer on the lower surface of the VCSEL chip is a second power electrode of the light-emitting chip, the second power electrode can be N (cathode) or P (anode), and the lower surface can be a large electrode due to the fact that the lower surface does not need to emit laser.

FIG. 6B shows an electrode lead-out mode of the EEL chip. The metal layer on the upper surface of the EEL chip is a first power electrode of the light-emitting chip, the first power electrode can be P (anode) or N (cathode), the lower surface metal layer of the EEL chip is a second power electrode of the light-emitting chip, the second power electrode can be N (cathode) or P (anode), and since light is emitted from the side surface of the chip, the upper surface and the lower surface do not need to emit laser and can be large electrodes.

FIG. 6C shows another electrode lead-out mode of the EEL chip. Since light is emitted from the side surface of the chip, both electrodes can be on the same surface of the chip. The lead-out mode is often suitable for small-power occasions. However, after the technology of the application is used, the method is even more suitable for high-power occasions.

The electrode lead-out mode of the switch chip is mainly two types, one type is that the current flow direction is perpendicular to the surface of the chip, that is, VMOS is represented, and as shown in FIG. 6D, the other type is that the current flow direction is parallel to the surface of the chip, that is, the LMOS is represented, and as shown in FIG. 6E.

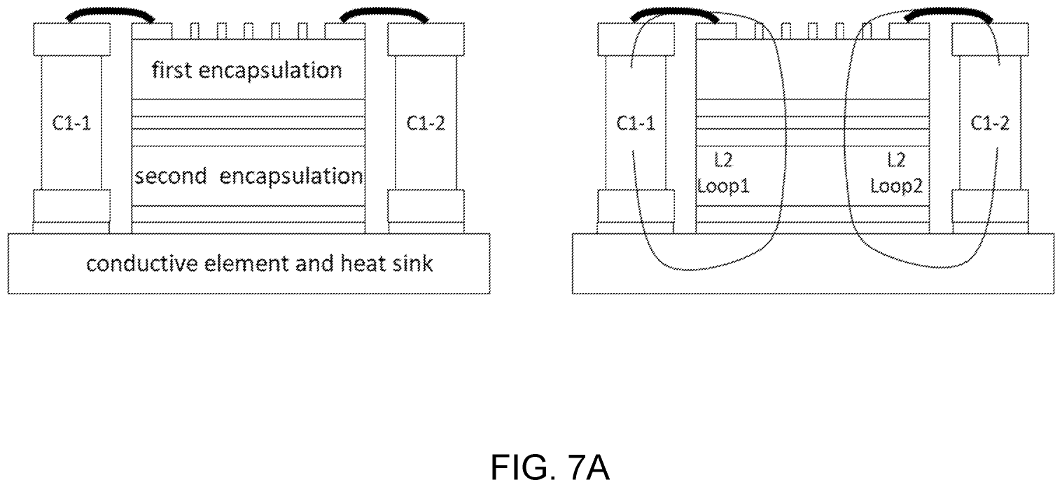

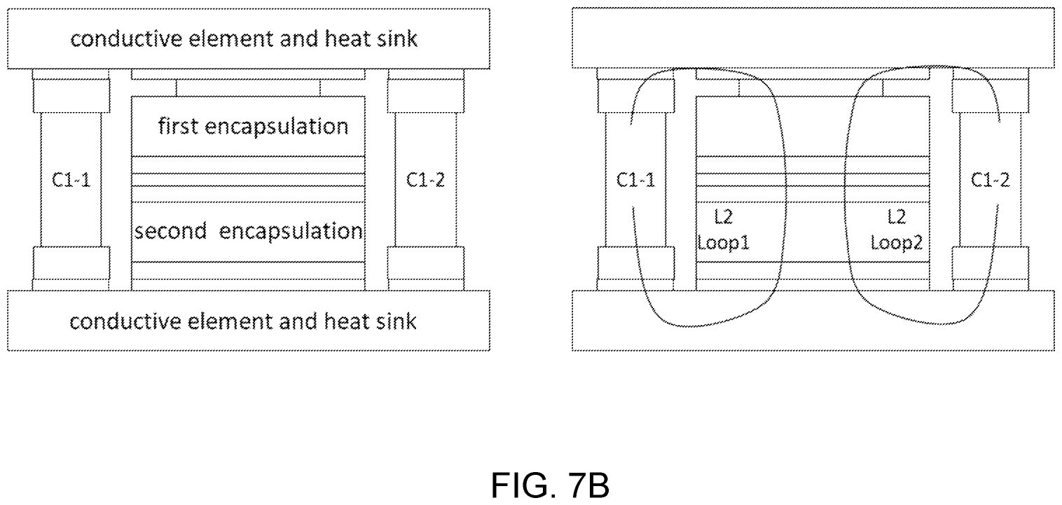

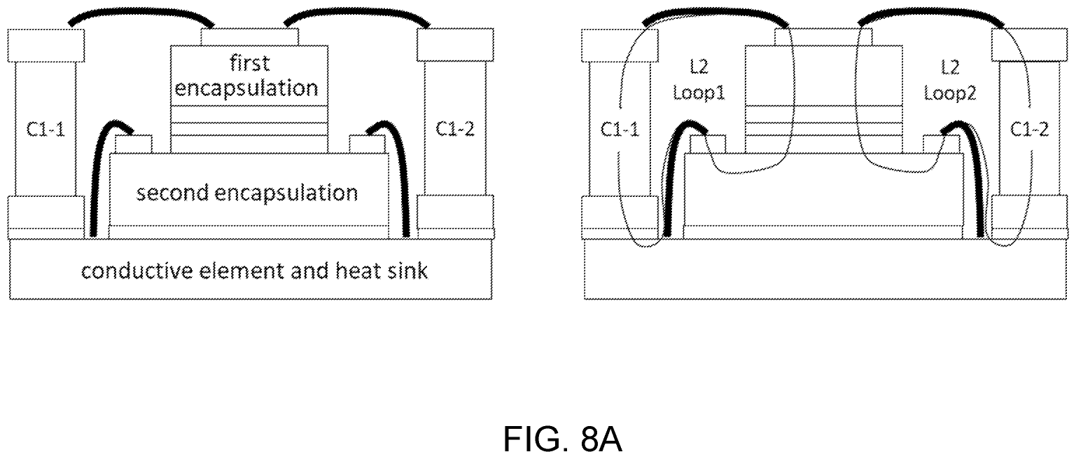

FIG. 7A and FIG. 7B are schematic diagrams when a light-emitting chip in which two power electrodes are located on an upper surface and a lower surface and switch chips having the same power electrodes on the upper surface and the lower surface are matched. The two structures are substantially the same, except that the used light-emitting chips are different. FIG. 7A is an embodiment employing a VCSEL chip, and FIG. 7B is an embodiment employing an EEL chip.

In FIG. 7A and FIG. 7B, the second power electrode of the light-emitting chip on the lower surface of the light-emitting chip is interconnected with the first power electrode of the switch chip on the upper surface of the switch chip in a large area, the interconnection mode can be direct chip-level die bond welding, also can each of the light-emitting chip and the switch chip or one of the light-emitting chip and the switch chip can be encapsulated and then welded together, and the light-emitting chip and the switch chip are stacked in parallel.

At least two sub-units C1-1 and C1-2 of the decoupling capacitor C1 are respectively placed on two sides of the stacked body, one end of C1-1 is electrically connected with a first power electrode of the light-emitting chip from the left side through a conductive element, and one end of C1-2 is electrically connected with a first power electrode of the light-emitting chip from the right side; and the other end of C1-1 and C1-2 is electrically connected with a second power electrode of the switch chip on the lower surface of the switch chip from the left side and the right side respectively. It can be seen that the module structure has two sub-loops with nearly equal, so that the loop inductance is greatly reduced. The conductive element is relative with encapsulation process, and can be provided with various methods, such as gold wires, copper wires, aluminum wires, lead frames or PCBs and DBC. The second power electrodes of the switch chip on the lower surface of the switch chip are interconnected, good thermal conductors such as large-region copper blocks, hot plate, heat pipes and the like can be used, the overall heat dissipation capacity of the laser module is improved, and the average emitting power is improved.

Due to the fact that the laser is emitted from the side face of the EEL chip, as shown in FIG. 7B, the upper surface and the lower surface can be interconnected through the conductive and thermal conduction material (i.e. conductive element and heat sink), electric connection is achieved, and good heat dissipation is achieved. The conductive and thermal conduction material is good in metal leadframe. A heat pipe/hot plate, a ceramic substrate, an aluminum substrate and the like can also be used for implementation. By means of the structure, heat dissipation of the upper surface of the light-emitting chip or heat dissipation of the lower surface of the switch chip or the combination of heat dissipation of the upper surface of the light-emitting chip and the lower surface of the switch chip can be flexibly achieved according to actual requirements, and the flexibility and the heat dissipation effect are greatly improved.

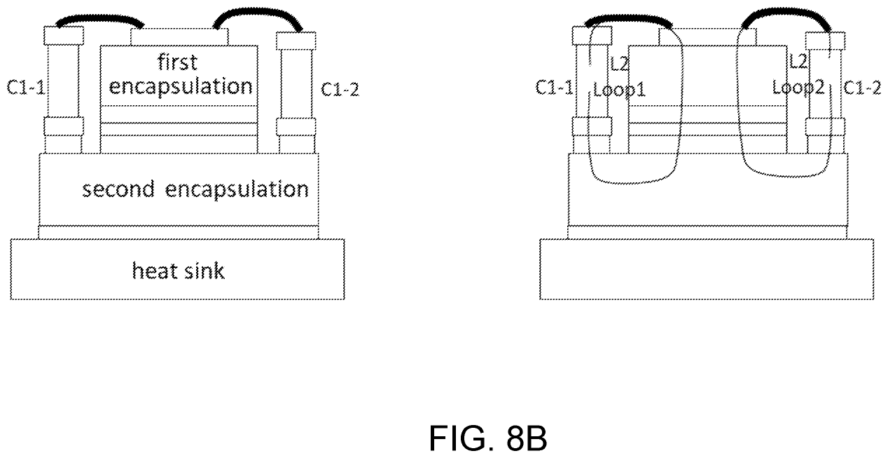

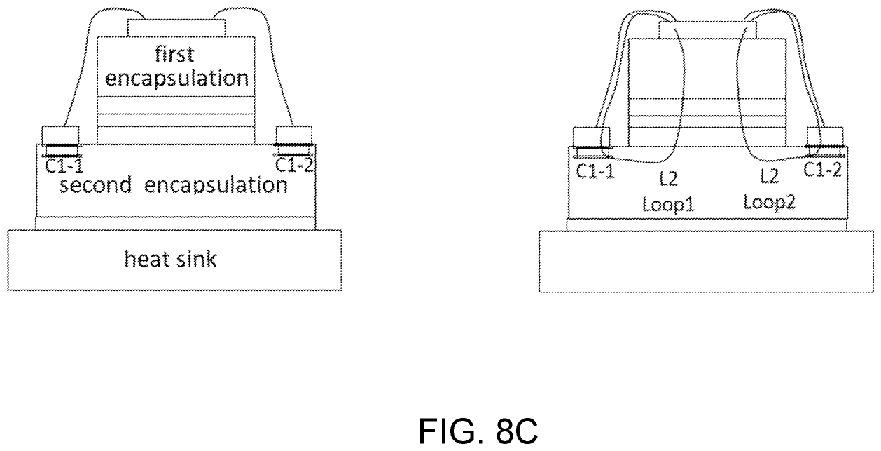

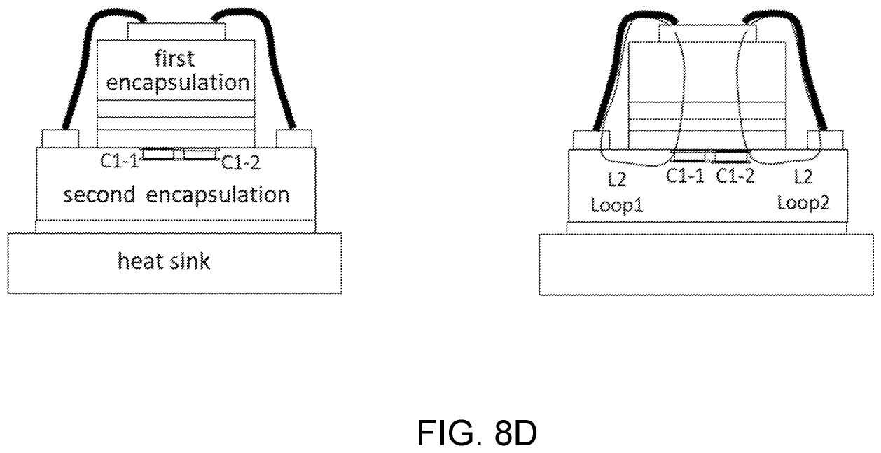

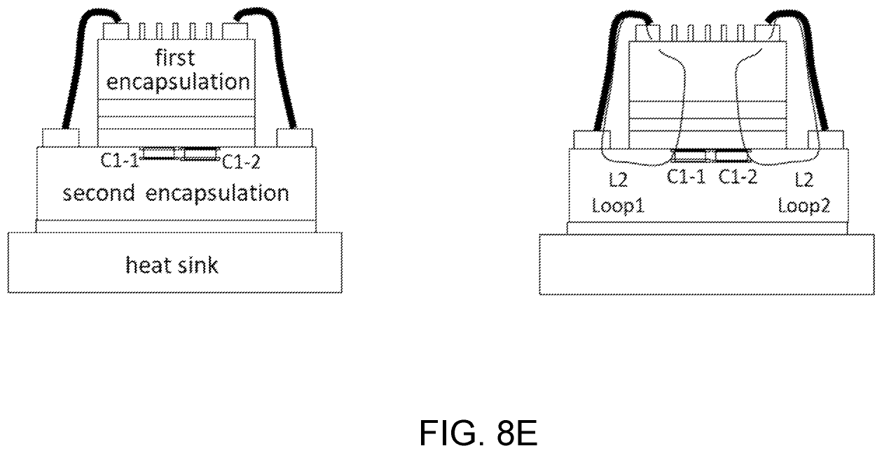

FIG. 8A to FIG. 8E show that the switch chip is a schematic diagram of the two power electrodes on the same surface (such as LMOS) of the switch chip, and the two power electrodes on the upper surface and the lower surface of the light-emitting chip.

As shown in FIG. 8A, the light-emitting chip is an EEL chip, two power electrodes of the light-emitting chip are on the different surfaces of the light-emitting chip, the first power electrode of the light-emitting chip in on the top, and the second power electrode of the light-emitting chip is on the bottom. The two power electrodes of the switch chip are on the upper of the switch chip. That is, the first electrode of the switch chip is in the center of the upper surface, the second electrodes of the switch chip are disposed on the two sides of the first electrode of the switch chip. The second power electrode of the light-emitting chip and the first power electrode of the switch chip are interconnected in a large area, the interconnection mode can be direct chip-level die bond welding, also can each of the light-emitting chip and the switch chip or one of the light-emitting chip and the switch chip can be encapsulated and then welded together, and the light-emitting chip and the switch chip are parallelly stacked. At least two sub-units C1-1 and C1-2 of the decoupling capacitor C1 are respectively placed on two sides of the stacked body. One end of C1-1 is electrically connected with a first power electrode of a light-emitting chip from the left side through a conductive element, and one end of C1-2 is electrically connected with a first power electrode of a light-emitting chip from the right side through a conductive element; and the other end of C1-1 and the other end of C1-2 are electrically connected with the corresponding second power electrode of the switch chip through the conductive element arranged on the bottom and one more conductive element to the second encapsulation from the left side and the right side respectively. It can be seen that compared with FIG. 7B, the current does not need to penetrate through the switch chip, so that the loop caused by the thickness of the switch chip is reduced, but the advantages of FIG. 7B are still reserved, and two nearly equal sub-Loops are also provided, so that the Loop inductance is lower. Although the lower surface of the switch chip does not need to be an electrode, due to the fact that the semiconductor material is a good thermal conductor, the lower surface of the switch chip can be thermally connected to an external device using for electric connection or thermal conduct at the same time, for example, a large-region copper block, a hot plate/heat pipe and the like, the overall heat dissipation capacity of the laser module is improved, and the average emitting power is improved. Due to the fact that the laser is emitted on the side face of EEL chip, in the embodiment shown in the FIG. 8A, the upper surface and the lower surface of module can be separately interconnected with external devices through the conductive and thermal conduction material, electric connection and good heat dissipation are both achieved. The conductive and thermal-conducting material can be metal leadframe or a heat pipe/hot plate, a ceramic substrate, an aluminum substrate and the like.

As shown in FIG. 8B, on the basis of FIG. 8A, decoupling capacitor C1 is directly stacked above the switch chip and is directly connected with a second power electrode of the switch chip. In this way, the conductive element of the decoupling capacitor C1 and the switch chip in FIG. 8A is removed, and the loop inductance is further reduced. Other advantages, such as heat dissipation, of FIG. 8A are still retained.

In some embodiments, the capacitance of the decoupling capacitor C1 allowed to be used in FIG. 8B is less than that used in FIG. 8A. Because the time level of of laser pulse emission is ns or even 0.1 ns, the required capacitance is very small, even at the nF level. In fact, even the decoupling capacitor C1 can be directly integrated in the switch chip through the semiconductor technology, namely the Cap In Die, and the electrical interconnection between the decoupling capacitor C1 and the switch chip is realized at the Die level. The decoupling capacitor C1 can be directly arranged in the switch chip in the integration process, and the decoupling capacitor C1 and the switch chip can also be encapsulated through the encapsulation technology, or the decoupling capacitor C1 can be integrated into the encapsulation formed by the switch chip or further encapsulated with the encapsulation of the switch chip.

As shown in FIG. 8C and FIG. 8D, the difference between the two is the position difference of decoupling capacitor C1 on the switch chip. One is distributed on both sides of the switch chip, and one is arranged in the center of one surface of the switch chip. Regardless, the interconnection and matching of the switch chip and the decoupling capacitor C1 are close to the left and right symmetry as much as possible. In this way, only the conductive element is needed between the two chips, so that the process difficulty and the structural complexity are simplified, and the loop inductance is further reduced. The heat dissipation flexibility and heat dissipation capability improvement measures can still be realized. The embodiment shown in FIG. 8D is suitable for the circuit schematic diagram shown in FIGS. 5A to 5C, namely, the implementation mode shared by the parts laser emitting device D1, the driving switch S1 and decoupling capacitor C1.

As shown in FIG. 8E, the embodiments of FIGS. 8A-8E are also applicable to VCSEL chips. For the sake of simplicity, only the similar structure of FIG. 8D is used for evidence production.

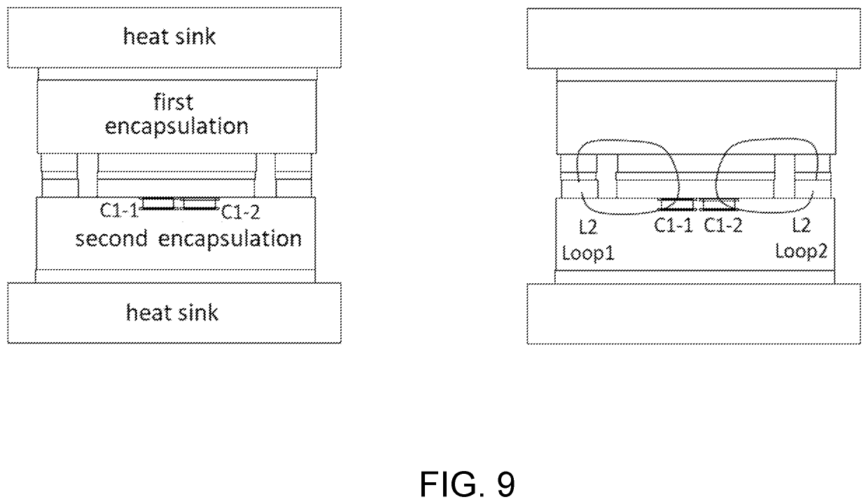

As before, the current loop at least penetrates through the thickness of one chip, and if the loop inductance needs to be further greatly reduced, a larger change is needed. As shown in FIG. 9, the light-emitting chip is an EEL chip, one surface of the light-emitting chip is provided with two different power electrodes, and the light-emitting chip is combined with a switch chip which is the same as a single-sided Pin and a decoupling capacitor C1, and Pin to Pin direct electrical interconnection is carried out in an inverted manner. In this way, the current loop does not need to penetrate any chips in the direction of thickness, and the region of a single loop is extremely small. A light-emitting chip or an encapsulation with three Pins is used in FIG. 9, that is, the light-emitting chip is provided with three pins disposed on the lower surface of the light-emitting chip, a first power electrode of the light-emitting chip is arranged in the center of the lower surface of the light-emitting chip, and the second power electrodes are arranged on the two sides of the first power electrode. In this way, the light-emitting chip can be divided into two axisymmetric sub-units with this arrangement. The second encapsulation is integrated with the decoupling capacitor C1, and the decoupling capacitor is electric interconnected with the switch chip. Three pins are disposed on the upper surface of the second encapsulation, A first electrode of the decoupling capacitor is arranged in the center of the upper surface, and second electrodes are arranged on the two sides of the first electrode of the decoupling capacitor, so that the arrangement of the second encapsulation integrated with the decoupling capacitor C1 is divided into two axisymmetric sub-units. After the first encapsulation and the second encapsulation are stacked by Pin to Pin and are welded together, the stacked body is a nearly perfect axisymmetric structure, the whole loop is formed by connecting two small sub-loops in parallel, and the loop inductance can be below 100 pH and is one sixth of the prior art. Moreover, electrical interconnection can be completed as long as one-time welding, so that the structure and the process are greatly simplified, the reliability is improved, and the cost is reduced. Due to the fact that the other surfaces of the two chips or the encapsulations do not need to be electrically interconnected with other devices and are flat in a large area, the two chips or the encapsulations can be directly and thermally interconnected to the radiator, and any one or even two heat dissipation effects of the two surfaces of the stacked body can be easily achieved.

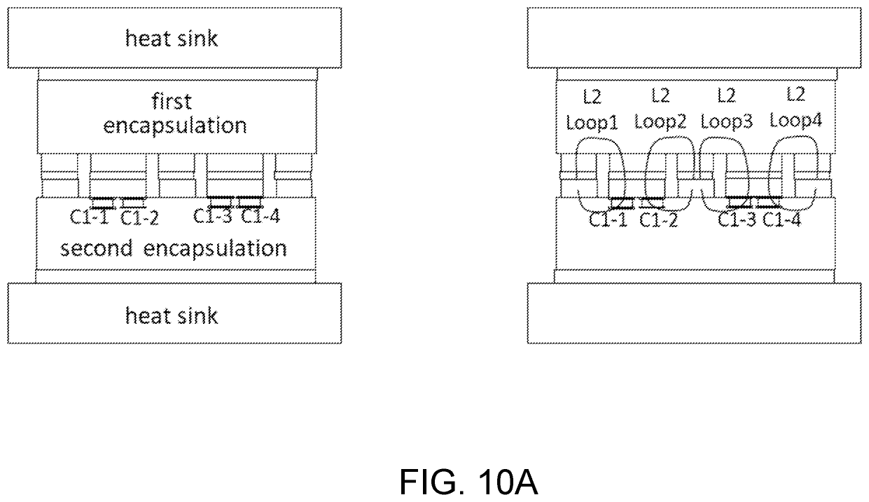

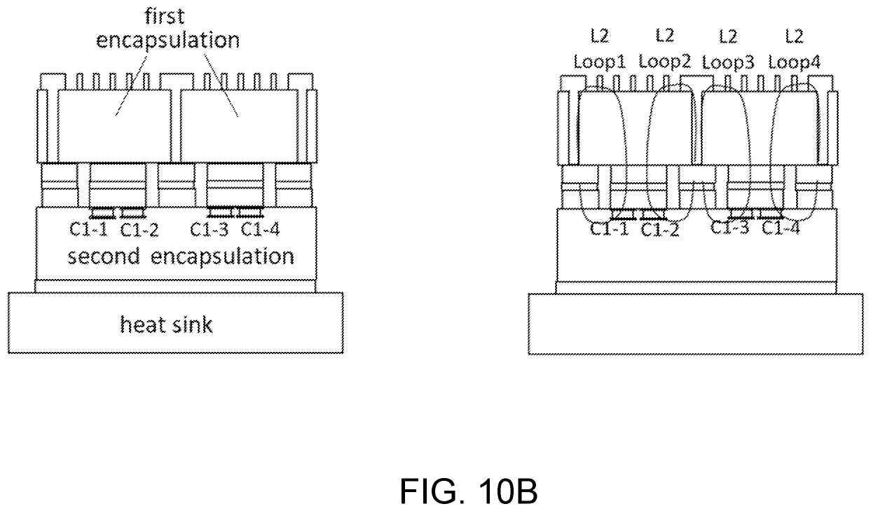

For a single-sided light-emitting chip or a first encapsulation having two different power electrodes, the effect thereof is not only that, as shown in FIG. 10A, the light-emitting chip or the encapsulation is divided into more sub-units, and the pins of each sub-unit are the same as that of FIG. 9. Similarly, the second encapsulation integrated with decoupling capacitor C1 is also divided into a similar number of sub-units, and each sub-unit is the same as that of FIG. 9. Each sub-unit of the light-emitting and corresponding sub-unit of the second encapsulation are buckled and electrically interconnected as in FIG. 9. In this way, more sub-units can be connected in parallel. The number of the sub-units is only limited by the precision of the interconnection process, the sub-units can be continuously improved, the loop inductance is greatly reduced, and the sub-units can be 50 pH or even 10 pH or below. Under the same level of process, the region of the light-emitting chip is increased by increasing the number of the sub-units as long as the number of the sub-units needs to be increased, and the transmission power is improved almost without increasing the falling edge time, the rising edge and the power supply voltage, FIG. 9 has the advantages of simple process flow, simple structure, high reliability, low cost, high heat dissipation capacity and the like of the heat dissipation multi-surface-interconnection, and the like.

For a single-sided light-emitting chip or a first encapsulation having two different power electrodes, the effect thereof is not only that, as shown in FIG. 10A, the light-emitting chip or the encapsulation is divided into more sub-units, and the pins of each sub-unit are the same as that of FIG. 9. Similarly, the second encapsulation integrated with decoupling capacitor C1 is also divided into a similar number of sub-units, and each sub-unit is the same as that of FIG. 9. Each sub-unit of the light-emitting and corresponding sub-unit of the second encapsulation are buckled and electrically interconnected as in FIG. 9. In this way, more sub-units can be connected in parallel. The number of the sub-units is only limited by the precision of the interconnection process, the sub-units can be continuously improved, the loop inductance is greatly reduced, and the sub-units can be 50 pH or even 10 pH or below. Under the same level of process, the region of the light-emitting chip is increased by increasing the number of the sub-units as long as the number of the sub-units needs to be increased, and the transmission power is improved almost without increasing the falling edge time, the rising edge and the power supply voltage, FIG. 9 has the advantages of simple process flow, simple structure, high reliability, low cost, high heat dissipation capacity and the like of the heat dissipation multi-surface-interconnection, and the like.

As stated above, in order to better achieve the spirit of the application, the application provides an innovative embodiment on the integration of a switch chip or an encapsulation, a light-emitting chip or an encapsulation and even a decoupling capacitor C1, and can also become a case of the application. According to the application, independent system description is carried out on the precise feeding of each element, and the element can be repeated with the previous possibility.

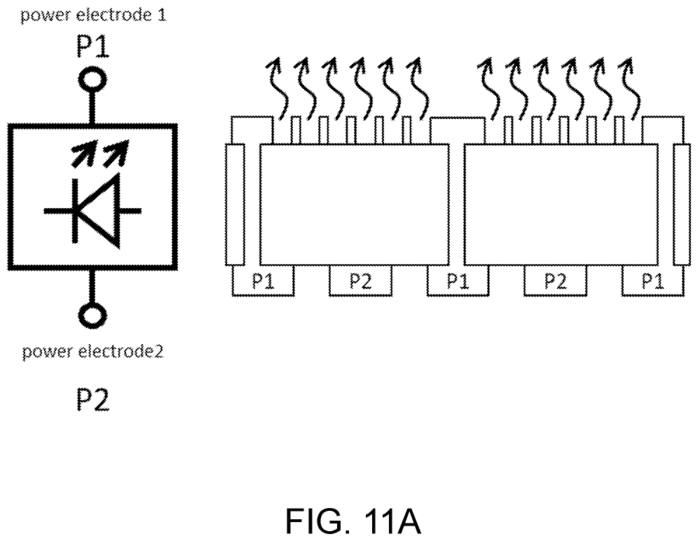

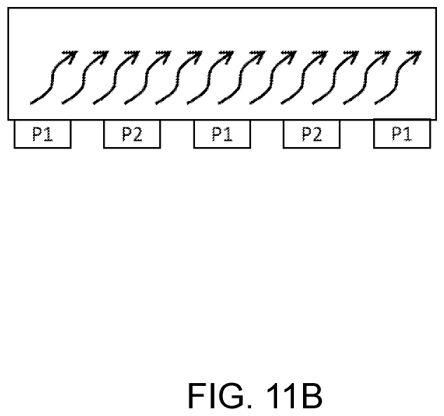

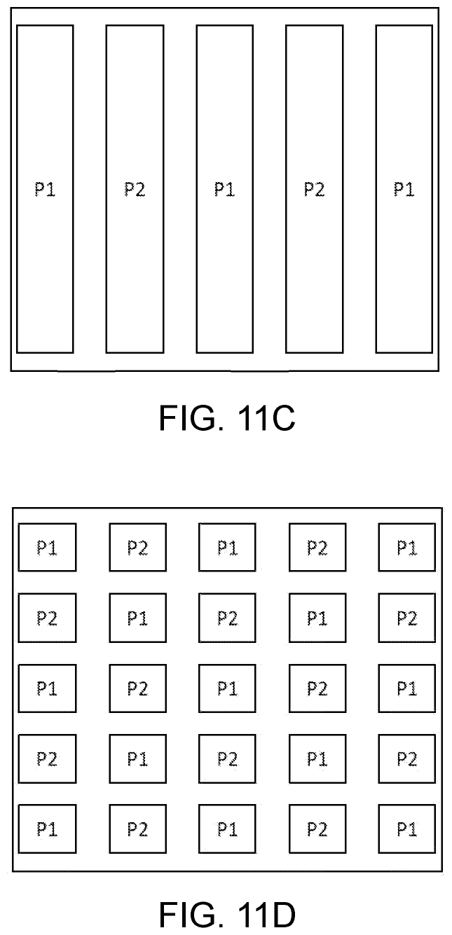

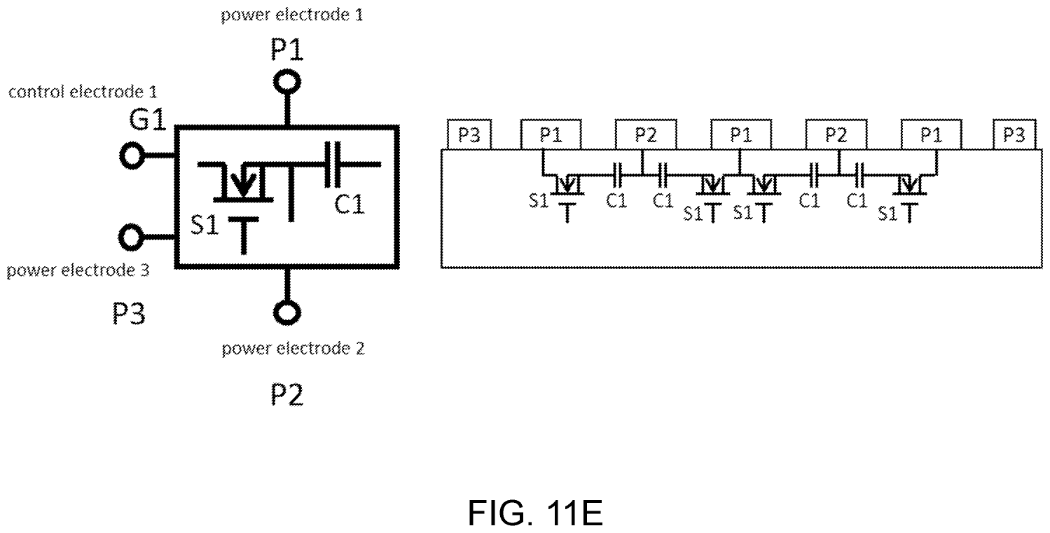

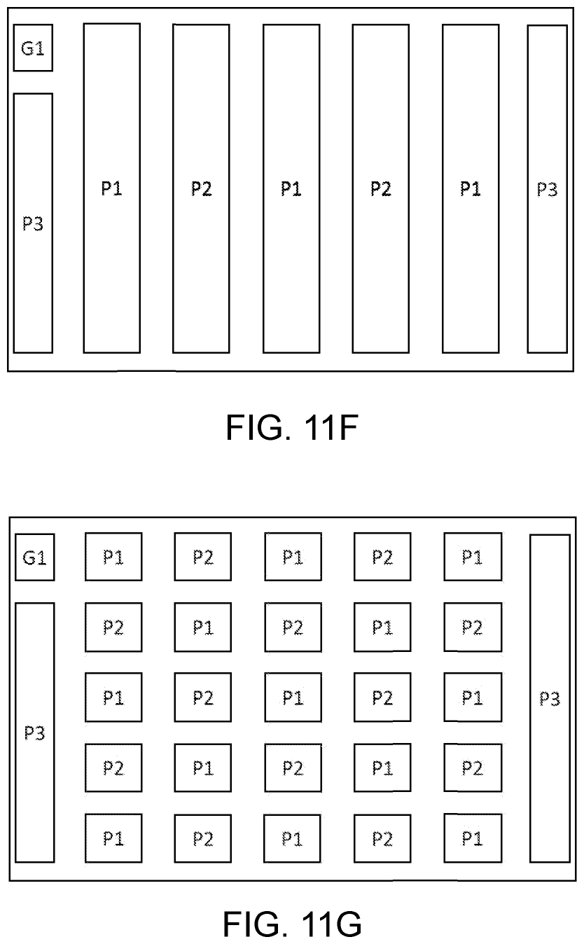

FIG. 11A is a cross-sectional view of a VCSEL chip including a plurality of sub-units. As described above, the first power electrode of the light-emitting chip on the same surface of the light-emitting window are electrically connected to the surface disposed the second power electrode of the light-emitting chip through the TSV technology. The total number of the first power electrode of the light-emitting chip and the second power electrode of the light-emitting chip is at least three, and the two same electric electrodes are disposed the two sides of one electrode with different electrical properties to form two sub-units which are combined in parallel. And the number of combinations is increased according to loop inductance or power requirements. Similarly, FIG. 11B is a cross-sectional view of an EEL chip, except that the light-emitting window is located on the side surface, the electrodes thereof are similar to each other to form at least two parts which are partially connected in parallel, and the number of sub-unit combinations can also be increased according to requirement. FIG. 11C is a chip electrode arrangement. The legends P1 and P2 are strip-shaped and are sequentially arranged alternately in parallel, so that the sub-units in the X direction are distributed in parallel. If the sub-units need to be divided into more sub-units, the sub-units can be sequentially placed in parallel in the Y direction under the condition of no challenge process precision, and the sub-units are sharply increased. In order to be matched with the light-emitting chip for use, the corresponding second encapsulation with the decoupling capacitor C1 is integrated, and at least one region is provided with electrodes corresponding to the light-emitting chips to be led out and arranged so as to be stacked to form the Loop effect as shown in FIGS. 10A and 10B.

FIG. 11E shows a cross-sectional view of a second encapsulation integrated with decoupling capacitor C1, FIG. 11F is an electrode layout diagram matched with FIG. 11C, and FIG. 11G is an electrode waterfall plot matched with FIG. 11D. The second encapsulation integrated with decoupling capacitor C1 is also formed by connecting a plurality of sub-units of decoupling capacitor C1 and the driving switch S1 in parallel. A plurality of sub-units of element D1 and sub-units of decoupling capacitor C1 and the driving switch S1 are formed after the sub-units of laser emitting device D1, the decoupling capacitor C1 and the driving switch S1 are interconnected, the equivalent numerous sub-loops are connected in parallel, and the loop inductance is extremely low. If FIG. 11D is matched with FIG. 11G, the equivalent loop inductance of loop 2 can be 50 pH or even lower.

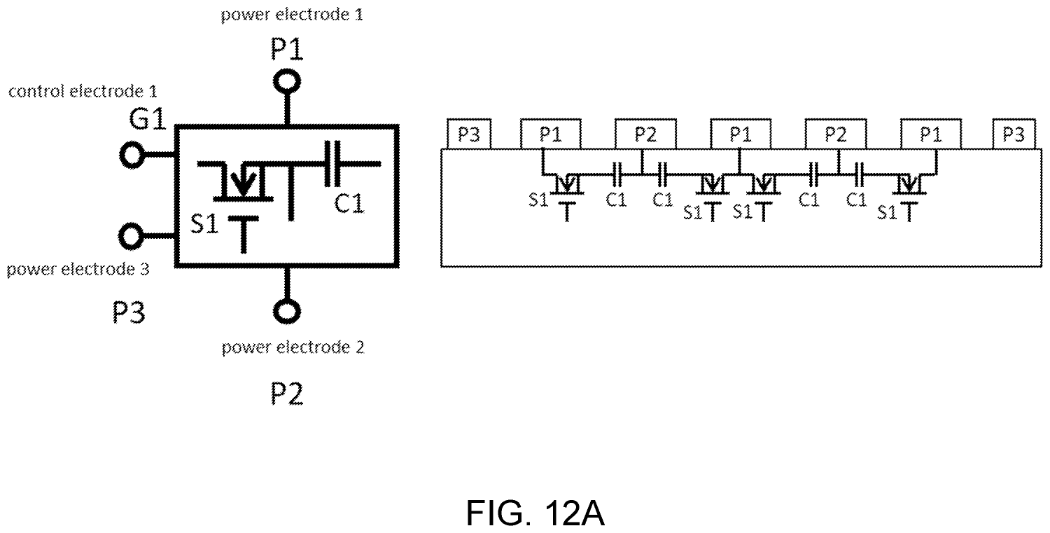

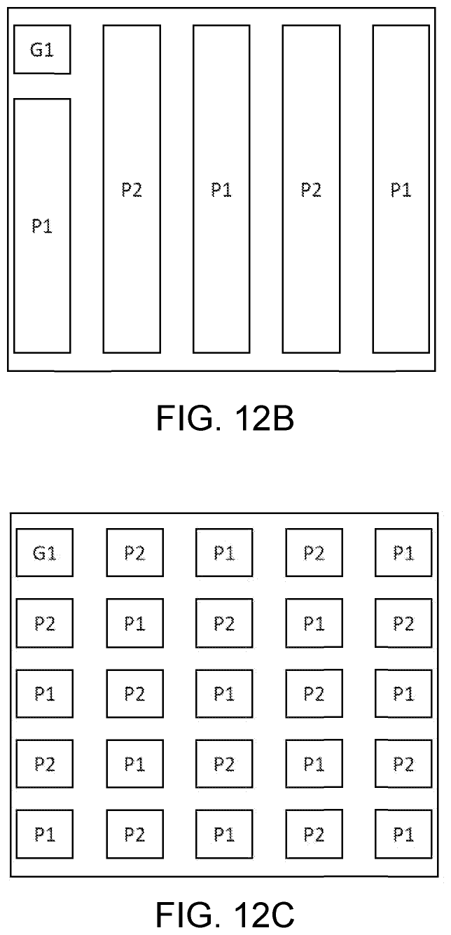

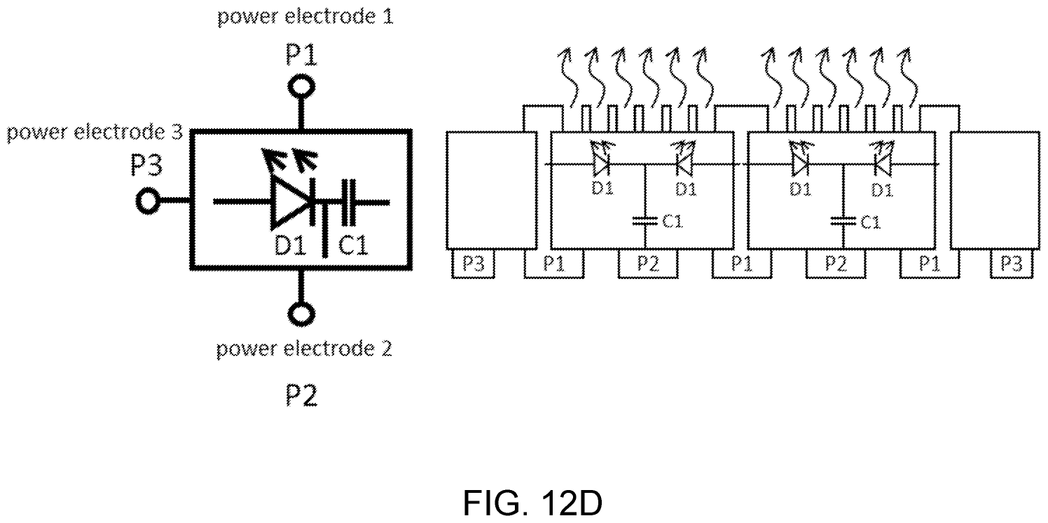

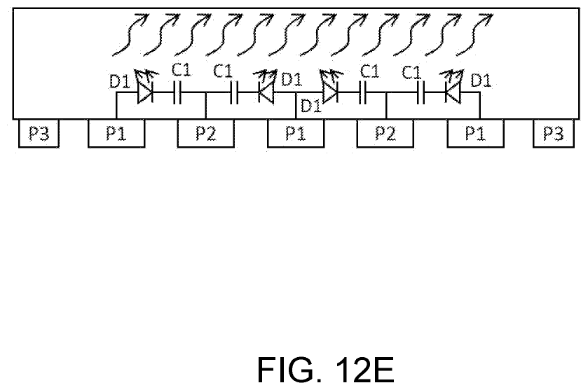

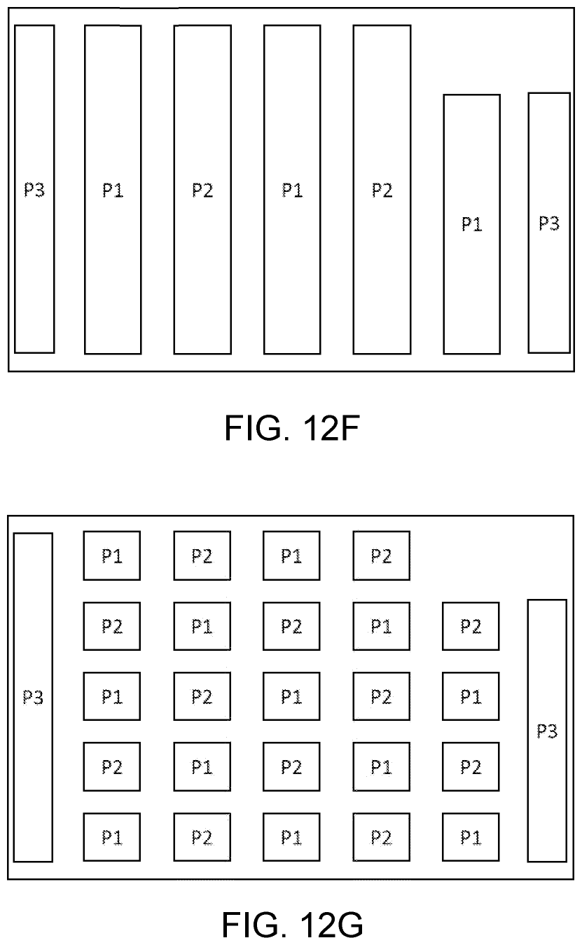

FIG. 11A to FIG. 11G are embodiments in which a decoupling capacitor C1 and a switch chip are integrated and combined, and FIGS. 12A-12G are similar in purpose, practice and effect of integrating decoupling capacitor C1 and a light-emitting chip in a chip level or a encapsulation level. FIG. 11A to FIG. 11G and FIG. 12A to FIG. 12G provide more options for the application.

It is emphasized that the embodiments of alternately arrangement of the electrodes can be many, and in addition to the exemplary strip-shaped and square shapes, annular, dot, rhombic, staggered wave shape or a combination of different shapes is suitable for the shape of the electrodes, and the arrangement cannot be limited. However, as long as the segmentation of at least two, even three and more than four sub-units is realized, the method can be used for the parallel effect of at least two, even three, four or more decoupling capacitor C1+the driving switch S1+laser emitting device D1, which are all within the spirit of the application.

Therefore, aiming at the descending of the loop inductance of laser emitting device D1, the driving switch S1 and decoupling capacitor C1, the application provides an innovation and meets the solutions and many embodiments required by different levels. The loop inductance can be greatly reduced, and the exponential time of the current change slope is allowed to rise. However, when the loop inductance is small to a certain degree, the limitation of the current efficiency is transferred to the switching speed of the driving switch S1. Therefore, the driving speed of the driving switch S1 is correspondingly improved.

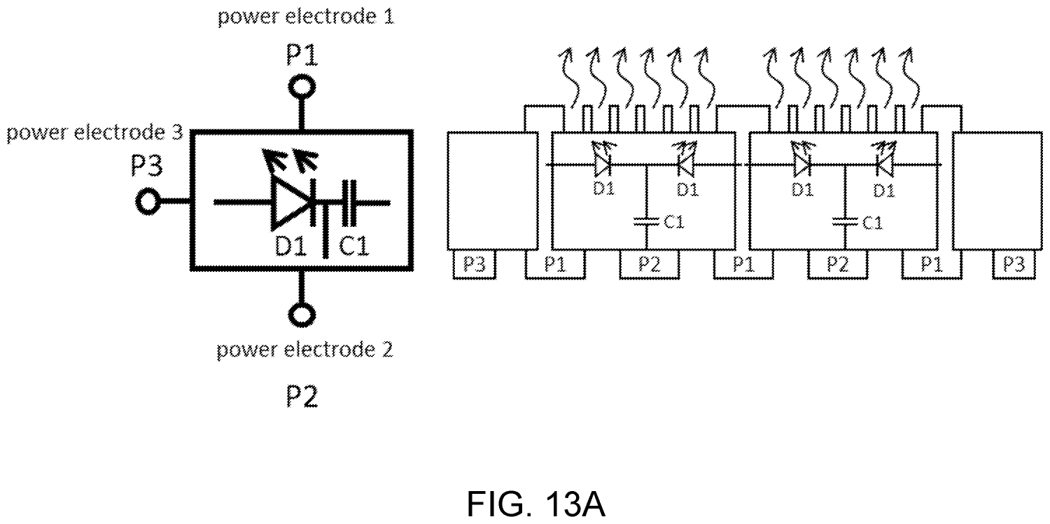

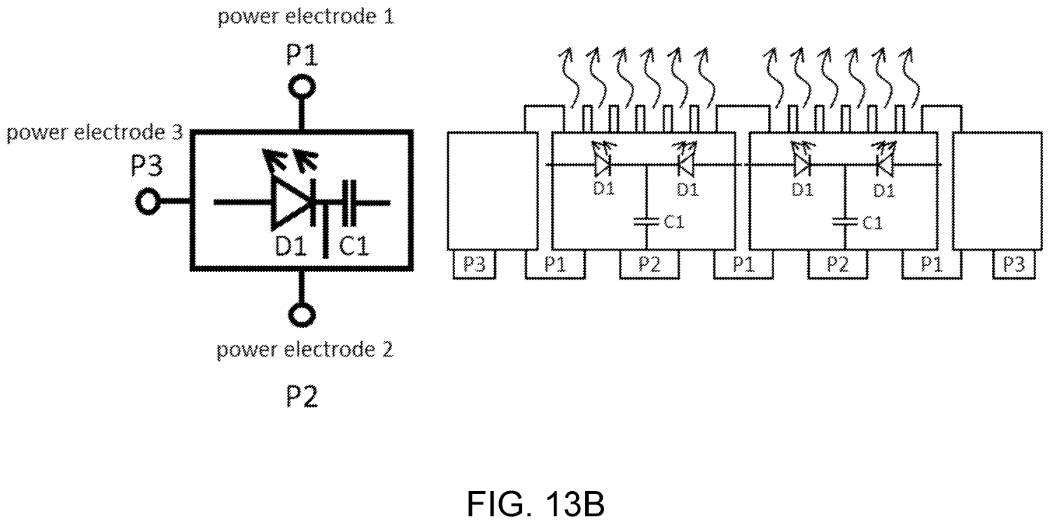

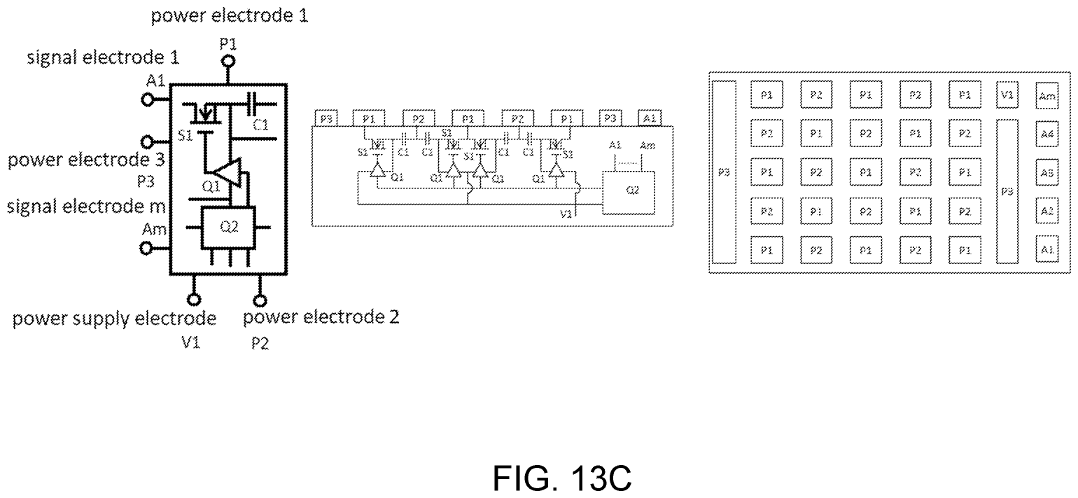

As shown in FIG. 13A, the switch driving unit Q1 of the driving switch S1 is integrated with the switch chip in the same encapsulation, the switch driving unit Q1 is also divided into a plurality of sub-units, so that all the sub-units of the driving switch S1 can be driven closely, the driving loop is reduced, and the driving speed is increased. Due to the introduction of switch driving unit Q1, in addition to reserving one control signal G1 to switch driving unit Q1, a power supply electrode V1 is needed for the driver.

As shown in FIG. 13B, at least a part of a power supply capacitor C2 driven in the driving switch S1 is integrated with the switch chip and connected with the power supply electrode V1 of switch driving unit Q1, energy is provided for driving nearby, and the reduction of the driving speed caused by the inductance of the power supply loop is reduced. Particularly, when necessary, the power supply capacitor C2 is also divided into a plurality of sub-units, so that each sub-unit of switch driving unit Q1 can obtain energy nearly, the driving loop is reduced, and the driving speed is increased.

As shown in FIG. 13C, the switch chip is more integrated into the operation control unit Q2. Since switch driving unit Q1 has been integrated, it means that the logic circuits and power devices are integrated together in the switch chip process, such as BCD, and monolithic integrated process. Therefore, the controller is easily to added in the switch chip. Therefore, the light-emitting chip is simplified, and the size is reduced, and the module is particularly suitable for mobile phones and automobile occasions with increasingly high requirements on the size. In this way, the core of the switching chip and even the laser-emitting chip has no control signal of the driving switch S1 (internally interconnected), a signal electrode for digital communication can be used, such as Al-Am, the intelligent control of the client system aren't needed, and the required laser pulse is emitted.

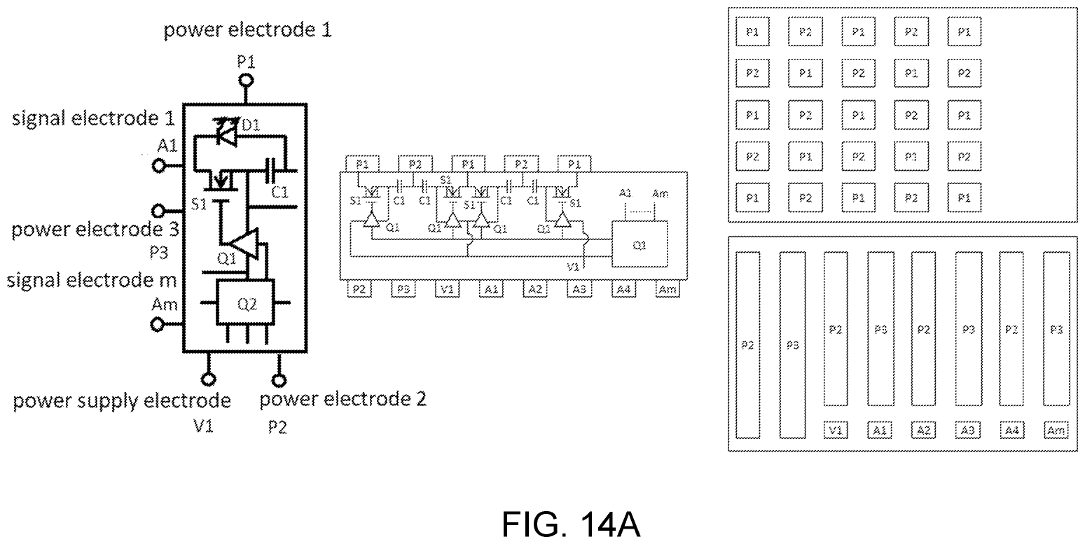

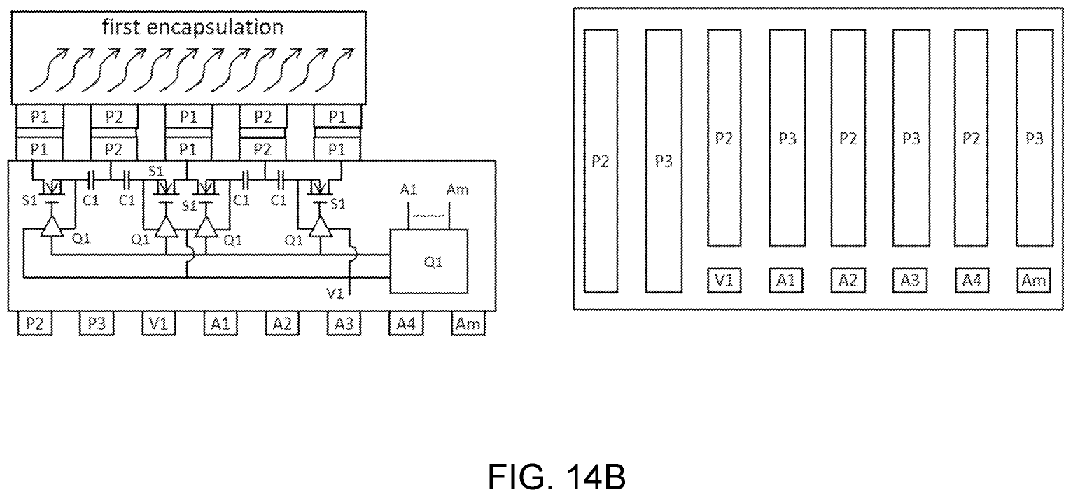

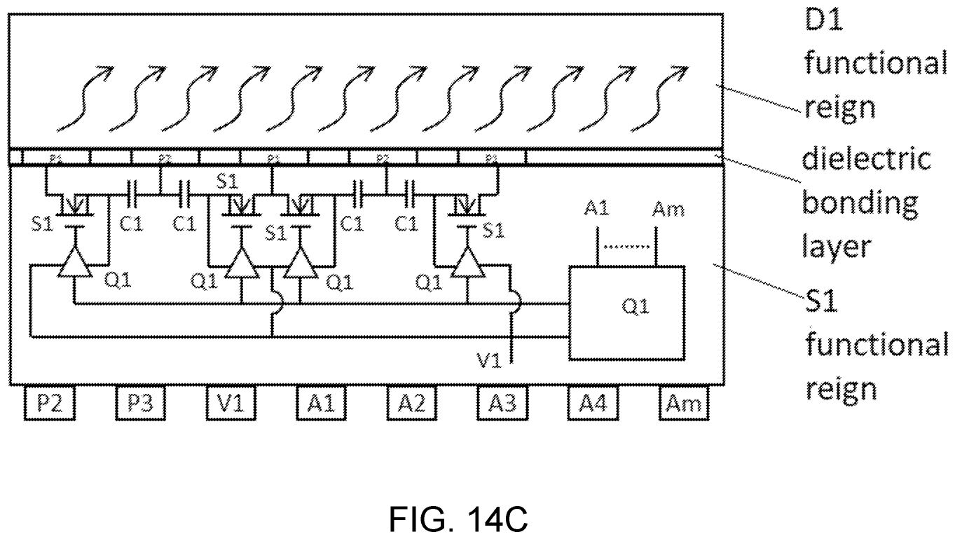

As shown in FIG. 14A, two type electrodes of a second encapsulation integrated with switch driving unit Q1, Q2, decoupling capacitor C1 and a switch chip are respectively arranged on the upper surface and the lower surface of the encapsulation. For example, the electrodes are disposed on the upper surface for interconnection with the light-emitting chip and the electrodes are disposed on the lower surface for interconnection with a client system.

As shown in FIG. 14B, a light-emitting chip or an encapsulation of the light-emitting chip or is inversely stacked and interconnected with the second encapsulation shown in FIG. 14A, so that a laser pulse emitting module with a complete function is formed. its size and performance are very excellent. Moreover, only one-time electrical bonding or welding interconnection is needed, and the production efficiency is very high.

As shown in FIG. 14C, all previous embodiments are formed by combining at least two chips. Along with the progress of the process capability, the semiconductor technology can be used on the surface of the laser chip, the processes such as growth and doping of the functional layer in the driving switch S1 are carried out, the integrated functions of the original switch chip and the like are completed, and All System in One Chip is realized. This is almost the extreme that the technology can develop, the performance will also be optimal, and the size is obviously minimum.

Specifically, in one embodiment, the laser pulse emitting module further comprises:
a D1 functional region of laser emitting device D1 is integrated with a D1 semiconductor structure for realizing the function of a laser emitting device D1, and the first surface of the D1 functional region is provided with a first power electrode of D1 functional region with the first electrical property and a second power electrode of D1 functional region with the second electrical property;
a S1 functional region is integrated with a C1 semiconductor structure for realizing a decoupling capacitor C1 function and is integrated with an S1 semiconductor structure for realizing the function of the driving switch S1, the C1 semiconductor structure is electrically connected with the S1 semiconductor structure, and the S1 functional region is provided with a first power electrode of the S1 functional region with the first electrical property and a second power electrode of the S1 functional region with the second electrical property;
a dielectric bonding layer is arranged between the D1 functional region and the S1 functional region, the dielectric bonding layer is bonded with the D1 functional region and the S1 functional region, a plurality of first conductors and a plurality of second conductors are arranged in the dielectric bonding layer, the first conductor electrically connects the first power electrode of the D1 functional region with the second power electrode of the S1 functional region, and the second conductor electrically connects the second power electrode of the D1 functional region with the first power electrode of the S1 functional region.

The manufacturing method of this embodiment, comprises the following steps:
a D1 functional region is formed on a wafer, the D1 functional region is integrated with a D1 semiconductor structure for realizing the function of a laser emitting device D1, a first power electrode and a second power electrode are formed on the first surface of the D1 functional region;
a dielectric bonding layer is grown over the first surface of the D1 functional region;
an SOI stack is disposed on the dielectric bonding layer, and an S1 functional region is formed on the SOI stack; the S1 functional region is integrated with a C1 semiconductor structure for realizing a decoupling capacitor C1 function and is integrated with an S1 semiconductor structure for realizing the function of the driving switch S1; the C1 semiconductor structure is electrically connected with the S1 semiconductor structure; the S1 functional region is provided with a first power electrode and a second power electrode of the S1 functional region;
a plurality of trenches is formed in the dielectric bonding layer and the S1 functional region, and the positions of the trenches are in one-to-one correspondence with the first power electrode and the second power electrode of the D1 functional region, so that the first power electrode and the second power electrode of the D1 functional region are exposed at the bottom of the trenches;
a plurality of first conductor and a plurality of second conductor are provided in the trench, the first conductor electrically connects the first power electrode of the D1 functional region to the second power electrode of the S1 functional region, and the second conductor electrically connects the second power electrode of the D1 functional region to the first power electrode of the S1 functional region.

In another embodiment, the laser pulse emitting module further includes:
a D1 functional region is integrated with a C1 semiconductor structure for realizing a decoupling capacitor C1 function, and is integrated with a D1 semiconductor structure for realizing the function of the laser emitting device D1, the C1 semiconductor structure is electrically connected with the D1 semiconductor structure, and the first surface of the D1 functional region is provided with a first power electrode with the first electrical property of D1 functional region and a second power electrode with the second electrical property of D1 functional region;
a S1 functional region is integrated with an S1 semiconductor structure for realizing a driving switch S1 function, and a first power electrode of S1 functional region with a first electrical property and a second power electrode of S1 functional region with a second electrical property are provided on the S1 functional region;
a dielectric bonding layer is arranged between the D1 functional region and the S1 functional region, the dielectric bonding layer is bonded with the D1 functional region and the S1 functional region, a plurality of first conductor and a plurality of second conductor are arranged in the dielectric bonding layer, the first conductor electrically connects the first power electrode of the D1 functional region with the second power electrode of the S1 functional region, and the second conductor electrically connects the second power electrode of the D1 functional region with the first power electrode of the S1 functional region.

The manufacturing method of this embodiment comprises the following steps:
A D1 functional region is formed on a wafer, the D1 functional region is integrated with a C1 semiconductor structure for realizing a decoupling capacitor C1 and is integrated with a D1 semiconductor structure for realizing the function of the laser emitting device D1, the C1 semiconductor structure is electrically connected with the D1 semiconductor structure, and the first surface of the D1 functional region is provided with a first power electrode of the D1 functional region of the first electrical property and a second power electrode of the D1 functional region with the second electrical property;
a dielectric bonding layer is grown over the first surface of the D1 functional region;
a SOI laminated layer is arranged on the dielectric bonding layer, and an S1 functional region is formed on the SOI laminated layer; the S1 functional region is integrated with an S1 semiconductor structure for realizing a driving switch S1 function, and the S1 functional region is provided with a first power electrode of the S1 functional region of the first electrical property and a second power electrode of the S1 functional region with the second electrical property;

A plurality of trenches is formed in the dielectric bonding layer and the S1 functional region, and the positions of the trenches are in one-to-one correspondence with the first power electrode of the D1 functional region and the second power electrode of the D1 functional region, so that the first power electrode of the D1 functional region and the second power electrode of the D1 functional region are exposed at the bottom of the trenches;

A plurality of first conductor and a plurality of second conductor are disposed in the trench, the first conductor electrically connects the first power electrode of the D1 functional region to the second power electrode of the S1 functional region, and the second conductor electrically connects the second power electrode of the D1 functional region to the first power electrode of the S1 functional region.

As can be seen from above, the driving switch S1 needs to be placed in a distributed manner, and various functions need to be formed through different interconnects, so that a plurality of micro-driving switches S1 are needed to be isolated each other, and therefore LMOS (i.e., a planar device) is better for the driving switch S1. Planar devices of silicon materials can be directly used for cost and technical maturity considerations. For performance and future trend considerations, GaN, i.e., gallium nitride devices, may be used. Certainly, along with the progress of the semiconductor, more devices capable of being integrated by the chip level can be generated, all the devices are within the options of the application, and the spirit of the application is not influenced.

According to the application, different levels of progress of the Loop formed by decoupling capacitor C1, the driving switch S1 and laser emitting device D1 of the laser pulse emitting module are refined, innovative and accurate feeding is also carried out on the key assembly, the excellent performance is achieved, the size is extremely small, and production and high reliability are also facilitated.

Therefore, as shown in FIG. 2, when the core feature is used for a client system, introduction of a power supply loop, namely the loop of Cin and L1, is needed, in order to avoid resonance of L1 and L2 and decoupling capacitor C1, avoid the generation of high-frequency current and the light noise, and a damping resistor R1 is needed to add in the power supply loop. In order to guarantee the working quality, R1 in the prior art needs to be as large as 1 kΩ, which is caused by overlarge inductance of L1. Obviously, the large resistance of R1 not only cause great power consumption, but also prolong the energy storage time of the decoupling capacitor C1. Before each laser pulse is emitted, the decoupling capacitor C1 must complete the process of energy storage, so that the interval time of laser pulse emission is prolonged, the limitation of system application is caused, and the innovation value of the application is influenced. Therefore, according to the embodiment of the application, the embodiment of solving this problem needs to be provided, and the inductance of L1 is reduced, so that the resistance of R1 is reduced, the high speed of single pulse and the short pulse interval is obtained.

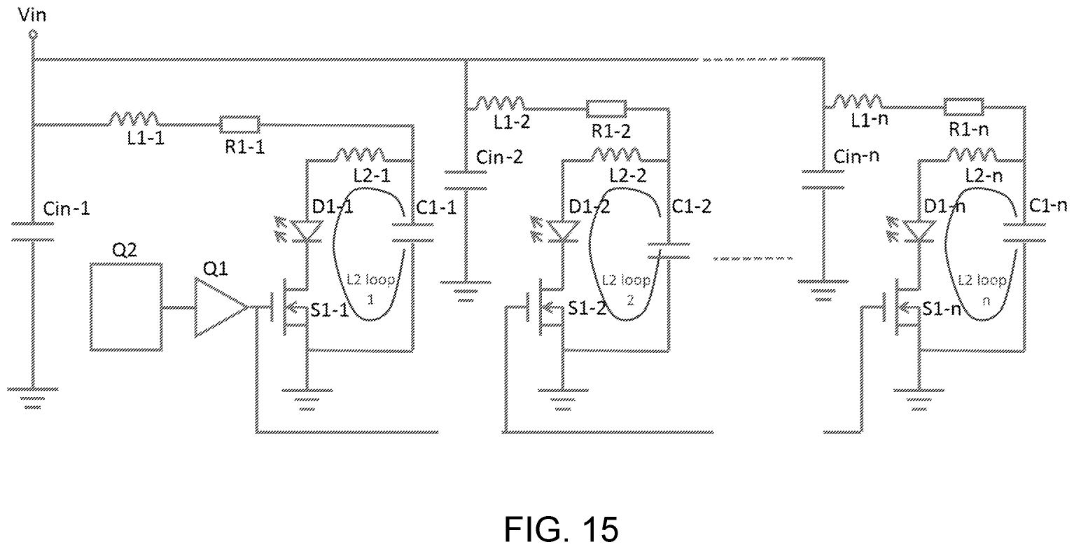

Therefore, as shown in FIG. 15, in some embodiments, a laser pulse emitting system, comprises: a laser pulse emitting module and a plurality of device groups of power supply loop;
the device group of power supply loop comprises a power supply capacitor Cin and a damping resistor R1 which are connected in series;
each device group of power supply loop and at least one energy storage sub-circuit form a sub-power supply loop;
the electrical connection between the power supply capacitor Cin and the damping resistor R1 is electrically connected with the power supply electrode of the laser pulse emitting system, the other end of the power supply capacitor Cin is grounded, and the other end of the damping resistor R1 is electrically connected with the power supply electrode of the energy storage sub-circuit.

The concept of descending of Loop 2 is used, namely, the series combination of Cin and R1 is also divided into at least two sub-units which are connected in parallel, so that the sub-energy storage loop can obtain the combined sub-unit of Cin and R1 nearby, the fact that the inductance of L1 of the Loop 1 is completely reduced, according to analysis, and the inductance of L1 can be reduced to 600 pH. The number of the combination of Cin and R1 is increased, so that the inductance of L1 can be further reduced to 300 pH.

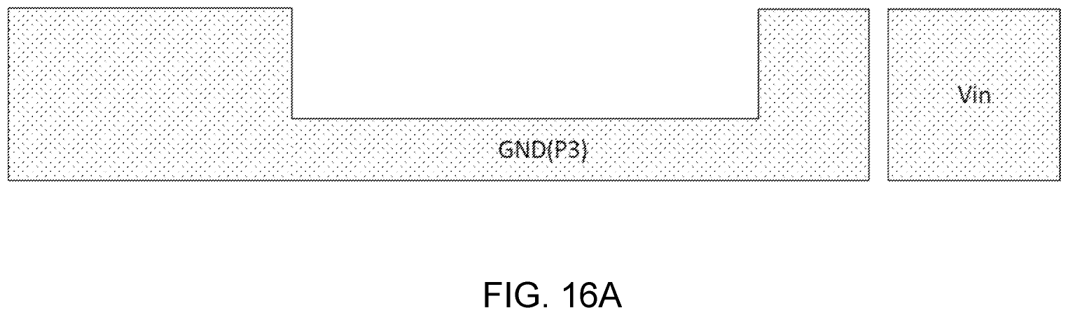

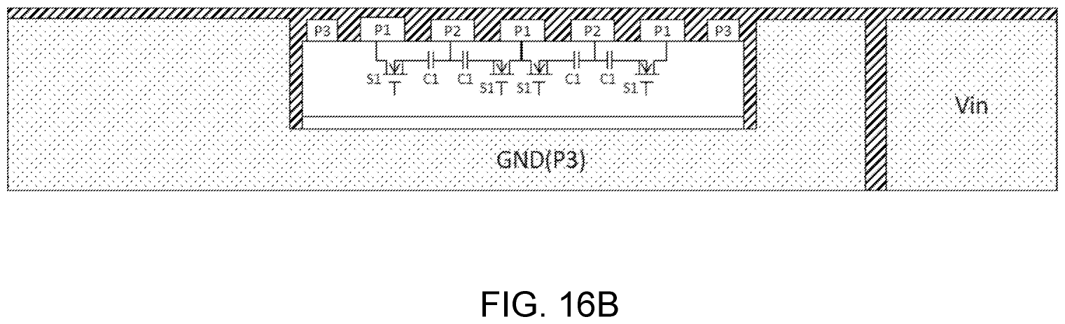

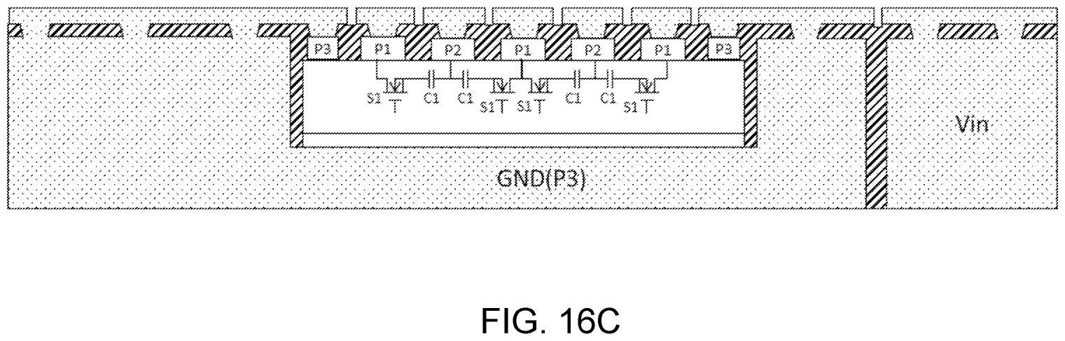

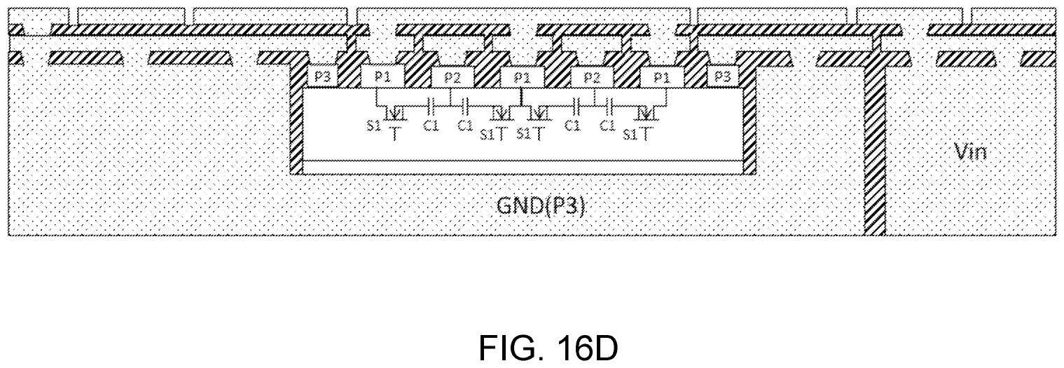

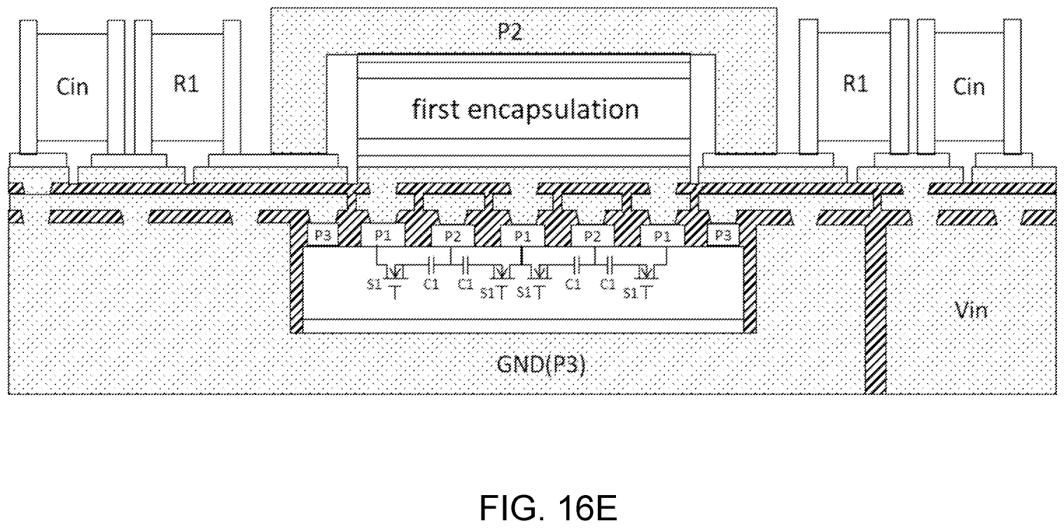

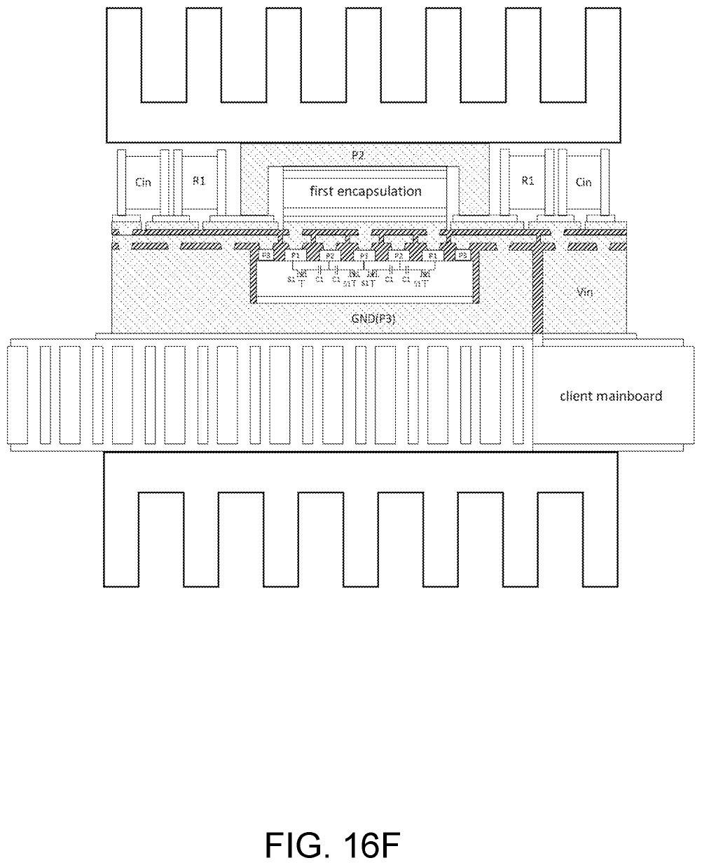

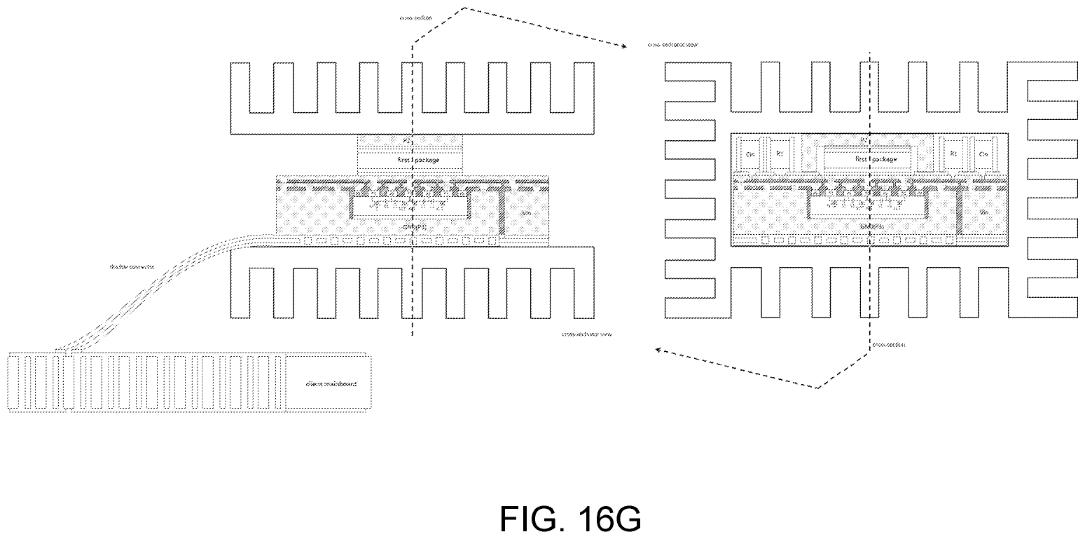

The manufacturability of the laser pulse emitting module of the application is described below with FIGS. 16A-16E, and the EEL chip is used as an example.

In the first step, as shown in FIG. 16A, a copper frame is pre-formed, and the pin of a laser pulse emitting module is disposed on the bottom of the pre-formed copper.

In the second step, as shown in FIG. 16B, the driving switch S1 of LMOS and the decoupling capacitor C1 are combined to form a combined chip, the electrode is disposed on the top surface of the combined chip, the bottom surface is thermally bonded to the copper frame, then the bonding body is covered with an insulating material, and the fixing and insulating effects are achieved. The insulator covers and extends beyond the electrode on the upper surface of the combined chip and the upper surface of the lead frame. However, with the requirement of the low thickness, the thickness of the combined chip should be 0.1 mm or 0.05 mm or less.

Thirdly, as shown in FIG. 16C, laser drilling, copper electroplating and etching are carried out on the insulating layer, a circuit layer similar to the PCB is made on the insulating layer, and the electrodes buried in the insulating layer are led out and interconnected.

In the fourth step, as shown in FIG. 16D, a layer of circuit layer is often insufficient. Then, an insulating layer is laid, punching, electroplating and etching are carried out, and a second layer of circuit layer is formed. If there is a need, a layer may be re-added. And finally, a bonding pad of a subsequent mounting element is reserved. In this way, the substrate embedded with the switch chip is made.

In the fifth step, as shown in FIG. 16E, solder is added to the bonding pad, and Cin, R1 and the encapsulated light-emitting chip are interconnected with the substrate of the driving switch S1 by using an SMD process. In this way, the manufacturing of the whole module is completed.

Of course, the actual manufacturing also has some detail steps, including that the panel containing a plurality of modules is cut into a single module after being produced at the same time.

The module is provided with the following features: a substrate embedded with the driving switch S1 and decoupling capacitor C1, wherein the upper surface and the lower surface are provided with PADs for power connection, wherein the lower surface is for interconnecting of customers, and the upper surface is for internally interconnected; and the middle position of the upper surface of the substrate is provided and welded with an encapsulation of the light-emitting chip. The lower surface of the light-emitting chip is vertically and electrically interconnected with the switch chip in a large area nearby through welding; the two sides of the encapsulation are disposed the other electrodes of the chip, and are respectively connected with at least one R1 through the substrate; and at least one Cin is interconnected with the corresponding R1. the space of Loop 1 or Loop 2 of the module are divided into at least two small sub-Loops, so that the double low-inductance requirements of L1 and L2 are met. Moreover, the upper surface and the lower surface of the module are respectively a large-region of the light-emitting chip and the switch chip for heat dissipation, and a better interface is provided for heat dissipation of the client application.

In practical implementation, as shown in FIG. 16F, the lower surface of the chip can be directly welded on the client mainboard, and the copper wire on the client mainboard is utilized to realize electrical intercommunication requirements and help thermal diffusion. a radiator, air cooling, water cooling and heat pipes can be directly added to the TOP copper frame of the light-emitting chip. In this way, the heat dissipation capacity is better, and the heat bottleneck caused by the fact that the two chips are integrated in one module is avoided. However, the technical difficulty of client application is improved, and the requirement for the thermal design capability of customers is high. The module may also be led out, welded, or plugged into the client system board using a flexible connector, and the heat dissipation is processed at the module level.

By taking a flexible PCB as a flexible connector, as shown in FIG. 16G, one part of a surface (i.e., which is named the end surface) of the flexible PCB can be welded below the lead-out end of the electrodes of the module, and the electric signal is led out to an end (i.e., which is named the signal end) of the flexible PCB and is interconnected with the client mainboard. A radiator is directly installed on the back face of the end surface of the flexible PCB. Due to the fact that the flexible PCB can be very thin, heat can be well led to the back face of the flexible PCB through the copper VIA, and good heat transfer is achieved in the state that the thickness is slightly increased. Due to the fact that the flexible PCB is transversely led out to the client mainboard, the radiator can be surrounded the module, that is, the radiator can be a shell at the same time, and only the light emitting window and the flexible line leading-out window are reserved. Therefore, the optimization of heat and electricity is completed at the module level, the challenge of the client application is almost reduced to the plug-and-play degree, and the method is very beneficial to presentation and application of the technical contribution of the application.

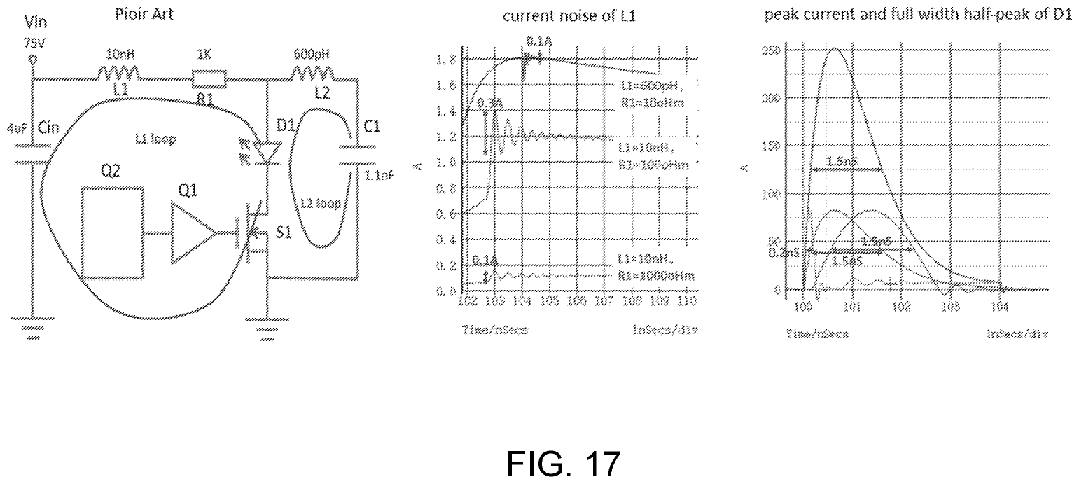

Compared with the prior art, the effect of the embodiment of the application is compared with that of the prior art. Parameters in the prior art are shown in FIG. 17 and table 1, the inductance of L1 is 10 nH, the resistance of R1 is 1 kΩ, the inductance of L2 is 600 pH, and it can be seen that if the resistance of R1 in the prior art is reduced to 100 omega, the high-frequency current noise of L1 is increased by 3 times. When the parameters of the embodiment of the application are L1=600 pH and L2=60 pH, the inductance of R1 only needs 10Ω, and the current noise amplitude is similar to the prior art of R1=1 kΩ. The inductance of R1 is reduced by 100 times, and the loss and the reduction and the charging time of decoupling capacitor C1 can be known.

TABLE 1
Comparison between the prior art and this application

| | | | R1 | | Peak | Full width | |
|---|---|---|---|---|---|---|---|
| Version | Vin | L1(H) | (ohm) | L2(pH) | current | Half-peak | Description |
| Prior Art | 75 V | 10 n | 1000 | 600 | 80 A | 1.5 ns | The parameters |
| | | | | | | | are obtained by |
| | | | | | | | simulating of a |
| | | | | | | | DEMO board of the |
| | | | | | | | supplies. |
| Equal width | 75 V | 600 p | 10 | 60 | 250 A | 1.5 ns | With equal width, |
| | | | | | | | the power can be |
| | | | | | | | increased to three |
| | | | | | | | times. |
| Equal height | 75 V | 600 p | 10 | 60 | 80 A | 0.2 ns | With equal |
| | | | | | | | height, power |
| | | | | | | | conditions, the |
| | | | | | | | speed can be |
| | | | | | | | increased to 7.5 |
| | | | | | | | times. |
| Equal width | 75 V | 600 p | 10 | 60 | 80 A | 1.5 ns | With equal width |
| and height | | | | | | | of height, the input |
| | | | | | | | voltage is reduced |
| | | | | | | | to ⅓. |

In Table 1, the “Equal width” means duration of FWHM (i.e., the full width at half maxima) of the control pulse is consistent with that of the existing design of the application; the “Equal height” means peak current of the control pulse is consistent with the existing design of the application; and when the “Equal width” and “Equal height” are implemented, the Vin is adjusted to enable the FWHM and peak current of the control pulse to be consistent with the existing design.

In the aspect of pulse quality, if the application is used, when the system is used for emitting the pulse with the same width as 1.5 ns in the prior art, the peak power can be increased to 3 times, and the detection distance when the system is used for the laser radar is greatly improved that the detection precision is not affected. When the same power is transmitted, the pulse width is reduced to one 7.5th of the existing design, that is, the speed is increased to 7.5 times, and the detection precision is greatly improved. When laser pulses corresponding to the quality of the prior art are transmitted, the power supply voltage can be reduced to one third of the prior art, the power consumption is further reduced, the withstand voltage of the driving switch S1 can be lower, and the performance and cost of wafer integration are more excellent.

Compared with the prior art, the application has the following beneficial effects:
(1) When the circuit function of laser pulse emission is realized, the energy storage circuit comprises N energy storage sub-circuits which are distributed at N adjacent sub-space positions of the integrated circuit module, the energy storage sub-circuits are arranged in the corresponding N sub-space positions to inhibit inductive coupling, and the equivalent Loop is parallel connection of the plurality of sub-loops, so that the equivalent Loop is far smaller than that of a traditional scheme, and the equivalent Loop inductance of 0.5 times or even more than 0.25 times can be easily obtained. Under the same condition, the speed of the rising edge of the laser pulse can be increased by two times or even more than four times. On the contrary, if the speed is not changed, the power supply voltage can be greatly reduced, the power consumption is also obviously reduced, meanwhile, the withstand voltage of the driving switch S1 can be reduced, and the same performance can be realized with lower cost. The low voltage of the driving switch S1 is also beneficial to subsequent higher integration, and the Loop inductance is further reduced. That is, the Lloop can be reduced from the original 600 pH to 150-300 pH or even lower.
(2) The series combination of Cin and R1 is also divided into at least two sub-units which are connected in parallel, so that the energy storage sub-circuits can obtain the combined sub-unit of Cin and R1 nearby, the fact that the inductance value L1 of the Loop 1 is completely feasible according to analysis and L1 is completely feasible is greatly reduced, and if yes, the combination number of Cin and R1 is increased, so that the the inductance of L1 is further reduced to 300 pH.

The above disclosed are only preferred embodiments of the invention and not intended to limit the scope of the invention. Therefore, equivalent changes made in accordance with the claims of the invention shall remain within the scope of the invention.

What is claimed is:

1. A laser pulse emitting integrated circuit module, used for realizing a circuit function for emitting a laser pulse, comprising:
at least one laser emitting device D1, used for emitting laser pulses;
at least one driving switch S1, wherein the driving switch S1 comprises at least one control electrode and is used for controlling the laser emitting device D1 to be turned on or off; and
at least one decoupling capacitor C1, used for receiving and storing electric energy provided by a system;
wherein the at least one laser emitting device D1, the at least one driving switch S1 and the at least one decoupling capacitor C1 are connected in pairs to form an energy storage circuit;
wherein when the circuit function for emitting the laser pulse is realizing, the energy storage circuit comprises N energy storage sub-circuits which are distributed at N adjacent sub-space positions of the laser pulse emitting integrated circuit module, and N is an integer greater than or equal to 2,
wherein the N energy storage sub-circuits are arranged in the corresponding N sub-space positions to inhibit inductive coupling,
wherein each of the N energy storage sub-circuits is controlled by the same control time sequence.

2. The laser pulse emitting integrated circuit module of claim 1, wherein two adjacent energy storage sub-circuits of the N energy storage sub-circuits share the same laser emitting device D1, and/or the same driving switch S1, and/or the same decoupling capacitor C1.

3. The laser pulse emitting integrated circuit module of claim 1, wherein the at least one laser emitting device D1 comprises a light-emitting chip, the light-emitting chip is a flat semiconductor chip, and the light-emitting chip is provided with a first power electrode with a first electrical property and a second power electrode with a second electrical property,
wherein the light-emitting chip forms a first encapsulation, and the first encapsulation is provided with a top surface of the first encapsulation and a bottom surface of the first encapsulation which are opposite,
wherein at least one the driving switch S1 comprises a switch chip, wherein the switch chip is a flat semiconductor chip, and the switch chip is provided with a first power electrode with a first electrical property and a second power electrode with a second electrical property,
wherein the switch chip forms a second encapsulation, and the second encapsulation is provided with a top surface of the second encapsulation and a bottom surface of the second encapsulation which are opposite,
wherein the first encapsulation and the second encapsulation are parallelly stacked up and down to form a stacked body,
wherein a contact surface between the first encapsulation and the second encapsulation is provided with a first direction and a second direction which are perpendicular to each other,
wherein the N energy storage sub-circuits are symmetrically arranged in the stacked body in the second direction.

4. The laser pulse emitting integrated circuit module of claim 3, wherein a deviation of a parallel angle between the overlapped light-emitting chip and the switch chip is in the range of −45° to +45°, and wherein a deviation of between central axes of the light-emitting chip and the switch chip is in the range of 2:3 to 3:2.

5. The laser pulse emitting integrated circuit module of claim 3, wherein the first power electrode of the switch chip is distributed on the top surface of the second encapsulation, and the second power electrode of the switch chip is distributed on the bottom surface of the second encapsulation,
wherein the first power electrode of the light-emitting chip is distributed on the top surface of the first encapsulation, and the second power electrode of the light-emitting chip is distributed on the bottom surface of the first encapsulation,
wherein the first power electrode of the switch chip is electrically connected with the second power electrode of the light-emitting chip,
wherein the at least one decoupling capacitor C1 in each of the N energy storage sub-circuits is arranged outside the stacked body, and two ends of the at least one decoupling capacitor C1 in each of the N energy storage sub-circuit are electrically connected with the second power electrode of the switch chip and the first power electrode of the light-emitting chip respectively.

6. The laser pulse emitting integrated circuit module of claim 3, wherein the first power electrode and second power electrode of the switch chip are respectively arranged on the top surface of the second encapsulation,
wherein the first power electrode of the light-emitting chip is distributed on the top surface of the first encapsulation, and the second power electrode of the light-emitting chip is distributed on the bottom surface of the first encapsulation,
wherein the first power electrode of the switch chip is electrically connected with the second power electrode of the light-emitting chip,
wherein the at least one decoupling capacitor C1 in each of the N energy storage sub-circuits is arranged outside of the stacked body, and two ends of the at least one decoupling capacitor C1 in each of the N energy storage sub-circuits are electrically connected with the second power electrode of the switch chip and the first power electrode of the light-emitting chip respectively.

7. The laser pulse emitting integrated circuit module of claim 3, wherein the at least one decoupling capacitor C1 in of the N each energy storage sub-circuits is integrated in the second encapsulation,
wherein in the second encapsulation, a second electrode of the at least one decoupling capacitor C1 in each of the N energy storage sub-circuits is electrically connected with the second power electrode of the switch chip,
wherein the first power electrode of the switch chip and a first power electrode of the at least one decoupling capacitor C1 are respectively arranged on the top surface of the second encapsulation,
wherein the first power electrode of the light-emitting chip is distributed on the top surface of the first encapsulation, and the second power electrode of the light-emitting chip is distributed on the bottom surface of the first encapsulation,
wherein the first power electrode of the switch chip is electrically connected with the second power electrode of the light-emitting chip,
wherein the first electrode of the at least one decoupling capacitor C1 is electrically connected with the first power electrode of the light-emitting chip from the outside of the stacked body.

8. The laser pulse emitting integrated circuit module of claim 3, wherein the decoupling capacitor C1 is integrated in the second encapsulation,
wherein in the second encapsulation, a second electrode of the at least one decoupling capacitor C1 is electrically connected with the second power electrode of the switch chip,
wherein the first power electrode of switch chip and a first electrode of the at least one decoupling capacitor C1 are respectively arranged on the top surface of the second encapsulation,
wherein the first power electrode of the light-emitting chip is distributed on the top surface of the first encapsulation, and the second power electrode of the light-emitting chip is distributed on the bottom surface of the first encapsulation,
wherein the first power electrode of the switch chip is electrically connected with the first power electrode of the light-emitting chip,
wherein the first electrode of the at least one decoupling capacitor C1 is electrically connected with the second power electrode of the light-emitting chip from the outside of the stacked body.

9. The laser pulse emitting integrated circuit module of claim 8, wherein at least some of the N energy storage sub-circuits share the same decoupling capacitor C1.

10. The laser pulse emitting integrated circuit module of claim 3, wherein the at least one decoupling capacitor C1 is integrated in the second encapsulation,
wherein in the second encapsulation, a second electrode of the at least one decoupling capacitor C1 is electrically connected with the second power electrode of the switch chip,
wherein the first power electrode of switch chip and a first power electrode of the at least one decoupling capacitor C1 are respectively arranged on the top surface of the second encapsulation,
wherein the first power electrode of a light-emitting chip and the second power electrode of a light-emitting chip are respectively arranged on the bottom surface of the first encapsulation,
wherein the first power electrode of the switch chip is electrically connected with the first power electrode of the light-emitting chip, and the first electrode of the at least one decoupling capacitor C1 is electrically connected with the second power electrode of the light-emitting chip.

11. The laser pulse emitting integrated circuit module of claim 10, further comprising:
a plurality of switch driving units Q1, wherein each of the plurality of switch driving unit Q1 is used for turning on and off of the switch chips, and each of the plurality of switch driving unit Q1 drives at least one of the switch chips,
wherein each of the plurality of the switch driving units Q1 is integrated in the second encapsulation,
wherein in the second encapsulation, each of the plurality of the switch driving units Q1 is electrically connected with a control electrode of the switch chip.

12. The laser pulse emitting integrated circuit module of claim 11, further comprising:
an operation control unit Q2, wherein the operation control unit Q2 is used for outputting a switch signal to each of the plurality of the switch driving units Q1, and the operation control unit Q2 drives the switch chip through at least one of the plurality of switch driving units Q1,
wherein the operation control unit Q2 is integrated in the second encapsulation,
wherein in the second encapsulation, the operation control unit Q2 is electrically connected with one of the plurality of the switch driving units Q1.

13. The laser pulse emitting integrated circuit module of claim 11, further comprising:
a plurality of power supply capacitors C2, wherein the plurality of power supply capacitors C2 are used for providing energy for the plurality of switch driving units Q1,
wherein each of the plurality of the power supply capacitor C2 is integrated in the second encapsulation,
wherein in the second encapsulation, two ends of each of the plurality of power supply capacitors C2 are electrically connected with a power supply electrode of each of the plurality of switch driving units Q1 and a grounding electrode of each of the plurality of the switch driving units Q1 respectively.

14. The laser pulse emitting integrated circuit module of claim 3, wherein the at least one decoupling capacitor C1 is integrated in the first encapsulation,
wherein in the first encapsulation, a second electrode of the at least one decoupling capacitor C1 is electrically connected with the second power electrode of the light-emitting chip,
wherein the first power electrode of the switch chip and the second power electrode of the switch chip are respectively arranged on the top surface of the second encapsulation,
wherein the first power electrode of the light-emitting chip and a first electrode of the at least one decoupling capacitor C1 are respectively arranged on the bottom surface of the first encapsulation,
wherein the first power electrode of the switch chip is electrically connected with the first power electrode of the light-emitting chip, and the second power electrode of the switch chip is electrically connected with the first electrode of the at least one decoupling capacitor C1.

15. The laser pulse emitting integrated circuit module of claim 10, wherein the first power electrode of the light-emitting chip or the second power electrode of the light-emitting chip is formed on the bottom surface of the first encapsulation through a through silicon via (TSV) technology.

16. The laser pulse emitting integrated circuit module of claim 10, wherein the first encapsulation and the second encapsulation are formed the stacked body by inverted manner.

17. The laser pulse emitting integrated circuit module of claim 10, wherein the first power electrode and the second power electrode of the light-emitting chip of the first encapsulation extend in a first direction and are distributed alternately in a second direction,
wherein the first power electrode of switch chip and a first electrode of the at least one decoupling capacitor C1 of the second encapsulation extend in the first direction and are distributed alternately in the second direction.

18. The laser pulse emitting integrated circuit module of claim 10, wherein the first power electrode and the second power electrode of the light-emitting chip of the first encapsulation are distributed alternately in a first direction and a second direction respectively,
wherein the first power electrode of the switch chip and a first electrode of the at least one decoupling capacitor C1 of the second encapsulation are distributed alternately in the first direction and the second direction respectively.

19. The laser module of claim 14, wherein the first power electrode of the light-emitting chip and a first electrode of the at least one decoupling capacitor C1 of the first encapsulation are extended in a first direction and are distributed alternately in a second direction,
wherein the first power electrode and second power electrode of the switch chip of the second encapsulation extend in the first direction and are distributed alternately in the second direction.

20. The laser module of claim 14, wherein the first power electrode of the light-emitting chip and a first electrode of the at least one decoupling capacitor C1 of the first encapsulation are distributed alternately in a first direction and a second direction respectively,
wherein the first power electrode and the second power electrode of the switch chip of the second encapsulation are distributed alternately in the first direction and the second direction respectively.

21. The laser pulse emitting integrated circuit module of claim 5, wherein the light-emitting chip is a vertical cavity surface emitting laser chip, and a heat dissipation device is arranged at a bottom of the stacked body.

22. The laser pulse emitting integrated circuit module of claim 5, wherein the light-emitting chip is an edge emitting chip, and a top of the stacked body and a bottom of the stacked body are respectively provided with a heat dissipation device.

23. The laser pulse emitting integrated circuit module of claim 1, further comprising:
a D1 functional region, integrated with a D1 semiconductor structure for realizing a function of the at least one laser emitting device D1, wherein a first surface of the D1 functional region is provided with first power electrodes of the D1 functional region with a first electrical property and second power electrodes of the D1 functional region with a second electrical property;
a S1 functional region, integrated with a C1 semiconductor structure for realizing a function of the at least one decoupling capacitor C1 and integrated with an S1 semiconductor structure for realizing a function of the at least one driving switch S1, wherein the C1 semiconductor structure is electrically connected with the S1 semiconductor structure, and the S1 functional region is provided with first power electrodes of the S1 functional region with a first electrical property and second power electrodes of the S1 functional region with a second electrical property; and
a dielectric bonding layer, disposed between the D1 functional region and the S1 functional region, wherein the dielectric bonding layer is bonded to the D1 functional region and the S1 functional region, a plurality of first conductors and a plurality of second conductors are provided in the dielectric bonding layer, the plurality of first conductors electrically connect the first power electrodes of the D1 functional region to the second power electrodes of the S1 functional region, and the plurality of second conductors electrically connect the second power electrodes of the D1 functional region to the first power electrodes of the S1 functional region.

24. The laser pulse emitting integrated circuit module of claim 1, further comprising:
a D1 functional region, integrated with a C1 semiconductor structure for realizing the function of the at least one decoupling capacitor C1, and integrated with a D1 semiconductor structure for realizing the function of the at least one laser emitting device D1, wherein the C1 semiconductor structure is electrically connected with the D1 semiconductor structure, and a first surface of the D1 functional region is provided with first power electrodes of the D1 functional region with a first electrical property and second power electrodes of the D1 functional region with a second electrical property;
a S1 functional region, integrated with an S1 semiconductor structure for realizing the functional of the at least one driving switch S1, wherein first power electrodes of the S1 functional region with a first electrical property and second power electrodes of the S1 functional region with a second electrical property are provided on the S1 functional region; and
a dielectric bonding layer, disposed between the D1 functional region and the S1 functional region, wherein the dielectric bonding layer is bonded to the D1 functional region and the S1 functional region, a plurality of first conductors and a plurality of second conductors are provided in the dielectric bonding layer, the plurality of first conductors electrically connect the first power electrodes of the D1 functional region to the second power electrodes of the S1 functional region, and the plurality of the second conductors electrically connect the second power electrodes of the D1 functional region to the first power electrodes of the S1 functional region.

25. The laser pulse emitting integrated circuit module of claim 23, wherein a surface of the dielectric bonding layer is provided with a third direction and a fourth direction which are perpendicular to each other,
wherein each of the plurality of first conductors and each of the plurality of second conductors respectively are extended in a first direction and in the third direction, and each of the plurality of first conductors and each of the plurality of second conductors are distributed alternately in the fourth direction.

26. The laser pulse emitting integrated circuit module of claim 23, wherein a surface of the dielectric bonding layer is provided with a third direction and a fourth direction which are perpendicular to each other,
wherein each of the plurality of first conductors and each of the plurality of second conductors are distributed alternately in the third direction and a fourth direction.

27. The laser pulse emitting integrated circuit module of claim 3, further comprising:
a flexible connector, arranged on the bottom surface of the second encapsulation, wherein the flexible connector is used for flexibly connecting the second encapsulation with a client mainboard and electrically connecting the second encapsulation with the client mainboard.

28. The laser pulse emitting integrated circuit module of claim 27, further comprising:
a heat dissipation shell, arranged on an outer side of the laser pulse emitting integrated circuit module, wherein an opening is formed in at least one direction of the heat dissipation shell, so that the heat dissipation shell does not block the laser pulses to be emitted, and the flexible connector does not blocked to extend to the client mainboard.

29. A method of making the laser pulse emitting integrated circuit module of claim 23, comprising:
manufacturing the D1 functional region on a wafer, wherein the D1 functional region is integrated with the D1 semiconductor structure for realizing the function of the at least one laser emitting device D1, and the first power electrodes of the D1 functional region and the second power electrodes of the D1 functional region are formed on the first surface of the D1 functional region;
growing the dielectric bonding layer over the first surface of the D1 functional region;
disposing a silicon on insulator (SOI) stack on the dielectric bonding layer and forming the S1 functional region on the SOI stack, wherein the S1 functional region is integrated with the C1 semiconductor structure for realizing the function of the at least one decoupling capacitor C1 and is integrated with the S1 semiconductor structure for realizing the function of the at least on driving switch S1, the C1 semiconductor structure is electrically connected with the S1 semiconductor structure, and the S1 functional region is provided with the first power electrodes of the S1 functional region and the second power electrodes of the S1 functional region;
forming a plurality of trenches in the dielectric bonding layer and the S1 functional region, wherein the positions of the plurality of trenches are in one-to-one correspondence with the first power electrodes of the D1 functional region and the second power electrodes of the D1 functional region, so that the first power electrodes of the D1 functional region and the second power electrodes of the D1 functional region are exposed at bottom of the trench; and
forming a plurality of first conductors and a plurality of second conductors in the trench, wherein the first conductors electrically connect the first power electrodes of the D1 functional region to the second power electrodes of the S1 functional region, and the plurality of second conductors electrically connect the second power electrodes of the D1 functional region to the first power electrodes of the S1 functional region.

30. A method of making the laser pulse emitting integrated circuit module of claim 24, comprising:
manufacturing the D1 functional region on a wafer, wherein the D1 functional region is integrated with the C1 semiconductor structure for realizing the function of the at least one decoupling capacitor C1 and is integrated with the D1 semiconductor structure for realizing the function of the at least one laser emitting device D1, the C1 semiconductor structure is electrically connected with the D1 semiconductor structure, and the first surface of the D1 functional region is provided with the first power electrodes with the first electrical property and the second power electrodes with the second electrical property;
growing the dielectric bonding layer over the first surface of the D1 functional region;
arranging a silicon on insulator (SOI) stack on the dielectric bonding layer, and forming the S1 functional region on the SOI stack, wherein the S1 functional region is integrated with the S1 semiconductor structure for realizing the function of the at least one driving switch S1, and the S1 functional region is provided with the first power electrodes of S1 functional region with the first electrical property and the second power electrodes of S1 functional region with the second electrical property;
forming a plurality of trenches in the dielectric bonding layer and the S1 functional region, wherein the positions of the plurality of trenches are in one-to-one correspondence with the first power electrodes of the D1 functional region and the second power electrodes of the D1 functional region, so that the first power electrodes of the D1 functional region and the second power electrodes of the D1 functional region are exposed at a bottom of the plurality of trenches; and
forming the plurality of first conductors and the plurality of second conductors in the plurality of trenches, wherein the plurality of first conductors electrically connect the first power electrodes of the D1 functional region to the second power electrodes of the S1 functional region, and the plurality of second conductors electrically connect the second power electrodes of the D1 functional region to the first power electrodes of the S1 functional region.

31. An encapsulation according to the first encapsulation of claim 17, wherein the light-emitting chip is a vertical cavity surface emitting laser (VCSEL) chip, the first power electrode of the light-emitting chip on the same surface of a light-emitting window is electrically connected to the surface disposed the second power electrode of the light-emitting chip through a TSV technology, or
wherein the light-emitting chip is an edge emitting laser (EEL) chip, the EEL chip comprises a plurality of light-emitting chip sub-units, and electrical properties of the adjacent light-emitting chip sub-units are opposite.

32. An encapsulation according to the second encapsulation of claim 17.

33. A laser pulse emitting system, comprising:
the laser pulse emitting integrated circuit module of claim 1 and a plurality of device groups of power supply loops,
wherein the plurality of device groups of power supply loops comprise a power supply capacitor Cin and a damping resistor R1 which are connected in series,
wherein each of the plurality of device groups of power supply loops and at least one energy storage sub-circuit form a sub-power supply loop,
wherein an electric connection position of the power supply capacitor Cin and the damping resistor R1 is electrically connected with a power supply electrode of the laser pulse emitting system, the other end of the power supply capacitor Cin is grounded, and the other end of the damping resistor R1 is electrically connected with the power supply electrode of the energy storage sub-circuit.
